(19) United States
(12) Patent Application Publication
(10) Pub. No.: US 2026/0082551 A1
(43) Pub. Date: Mar. 19, 2026

(54) Semiconductor Device

(71) Applicant: Semiconductor Energy Laboratory Co., Ltd., Kanagawa-ken (JP)

(72) Inventors: Shunpei YAMAZAKI, Setagaya, Tokyo (JP); Takanori MATSUZAKI, Atsugi, Kanagawa (JP); Atsushi MIYAGUCHI, Hadano, Kanagawa (JP)

(73) Assignee: Semiconductor Energy Laboratory Co., Ltd., Kanagawa-ken (JP)

(21) Appl. No.: 19/108,625

(22) PCT Filed: Sep. 4, 2023
(86) PCT No.: PCT/IB2023/058718

§ 371 Date: Mar. 4, 2025

(30) Foreign Application Priority Data
Sep. 9, 2022 (JP) 2022-143757

(51) Int. Cl. H10B 12/00; G11C 11/4091

(52) U.S. Cl. CPC H10B 12/50; G11C 11/4091; H10B 12/33

(57) ABSTRACT

A semiconductor device with a novel structure is provided. A first element layer provided with a reading circuit, a second element layer provided with an amplifier circuit, and a third element layer provided with a memory cell are included. The second element layer is stacked over the first element layer. The third element layer is stacked over the second element layer. The memory cell and the amplifier circuit are electrically connected to each other through a first bit line. The amplifier circuit and the reading circuit are electrically connected to each other through a second bit line. The amplifier circuit has a function of transmitting a signal corresponding to a potential of the first bit line to the second bit line. The amplifier circuit includes a first transistor in which a first semiconductor layer including a channel formation region includes an oxide semiconductor. The memory cell includes a second transistor in which a second semiconductor layer including a channel formation region includes an oxide semiconductor and a capacitor. The first semiconductor layer is provided in a direction parallel to a surface of a substrate provided with the first element layer. The second semiconductor layer is provided in a direction perpendicular to the surface of the substrate provided with the first element layer.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter. Thus, more specific examples of the technical field of one embodiment of the present invention disclosed in this specification include a semiconductor device, a display device, a light-emitting device, a power storage device, a memory device, a driving method thereof, and a manufacturing method thereof.

### BACKGROUND ART

In recent years, research and development have been actively conducted on a structure in which a plurality of dies (e.g., silicon dies) provided with circuits having different functions, such as SRAM cells or DRAM cells, are stacked three-dimensionally (e.g., Non-Patent Document 1 and Non-Patent Document 2).

Moreover, in recent years, technical development of a semiconductor device capable of retaining electric charge corresponding to data with the use of a transistor using an oxide semiconductor in a channel formation region (hereinafter an OS transistor) has progressed. A layer including an OS transistor can be stacked over a die including a transistor using silicon in a channel formation region (hereinafter a Si transistor). Patent Document 1 discloses a structure in which a plurality of layers including OS transistors are stacked three-dimensionally over a die including Si transistors.

### REFERENCES

### Patent Document

[Patent Document 1] PCT International Publication No. 2020/152522

### Non-Patent Documents

[Non-Patent Document 1] W. Gomes et al., ISSCC Dig. Tech. Papers, pp. 42-43, 2022.

[Non-Patent Document 2] M. Park et al., ISSCC Dig. Tech. Papers, pp. 444-445, 2022.

### SUMMARY OF THE INVENTION

### Problems to be Solved by the Invention

An object of one embodiment of the present invention is to provide a semiconductor device or the like having a novel structure. Another object of one embodiment of the present invention is to provide a semiconductor device or the like functioning as a memory device that utilizes retention of electric charge corresponding to data and having a novel structure that excels in low power consumption. Another object of one embodiment of the present invention is to provide a semiconductor device or the like functioning as a memory device that utilizes retention of electric charge corresponding to data and having a novel structure that allows a reduction in the size of the device. Another object of one embodiment of the present invention is to provide a semiconductor device or the like functioning as a memory device that utilizes retention of electric charge corresponding to data and having a novel structure that excels in the reliability of data to be read.

Note that the objects of one embodiment of the present invention are not limited to the objects listed above. The objects listed above do not preclude the existence of other objects. Note that the other objects are objects that are not described in this section and will be described below. The objects that are not described in this section are derived from the description of the specification, the drawings, and the like and can be extracted as appropriate from the description by those skilled in the art. Note that one embodiment of the present invention is to solve at least one of the objects listed above and/or the other objects.

### Means for Solving the Problems

One embodiment of the present invention is a semiconductor device including a first element layer provided with a reading circuit, a second element layer provided with an amplifier circuit, and a third element layer provided with a memory cell; the second element layer is stacked over the first element layer; the third element layer is stacked over the second element layer; the memory cell and the amplifier circuit are electrically connected to each other through a first bit line; the amplifier circuit and the reading circuit are electrically connected to each other through a second bit line; the amplifier circuit has a function of transmitting a signal corresponding to a potential of the first bit line to the second bit line; the amplifier circuit includes a first transistor in which a first semiconductor layer including a channel formation region includes an oxide semiconductor; the memory cell includes a second transistor in which a second semiconductor layer including a channel formation region includes an oxide semiconductor and a capacitor; the first semiconductor layer is provided in a direction parallel to a surface of a substrate provided with the first element layer; and the second semiconductor layer is provided in a direction perpendicular to the surface of the substrate provided with the first element layer.

In the semiconductor device of one embodiment of the present invention, the capacitor is preferably provided in an opening portion provided in the second element layer and the opening portion preferably includes a region overlapping with the second semiconductor layer.

In the semiconductor device of one embodiment of the present invention, the first transistor preferably includes a gate and a back gate, and the back gate preferably includes a region overlapping with the gate.

In the semiconductor device of one embodiment of the present invention, a plurality of element layers are preferably stacked in the third element layer.

In the semiconductor device of one embodiment of the present invention, the oxide semiconductor preferably includes In, Ga, and Zn.

### Effect of the Invention

Note that other embodiments of the present invention are shown in the description of the following embodiments and the drawings.

With one embodiment of the present invention, a semiconductor device or the like having a novel structure can be provided. With another embodiment of the present invention, a semiconductor device or the like functioning as a memory device that utilizes retention of electric charge corresponding to data and having a novel structure that excels in low power consumption can be provided. With another embodiment of the present invention, a semiconductor device or the like functioning as a memory device that utilizes retention of electric charge corresponding to data and having a novel structure that allows a reduction in the size of the device can be provided. With another embodiment of the present invention, a semiconductor device or the like functioning as a memory device that utilizes retention of electric charge corresponding to data and having a novel structure that excels in the reliability of data to be read can be provided.

Note that the description of these effects does not preclude the existence of other effects. One embodiment of the present invention does not need to have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B are diagrams each illustrating a structure example of a semiconductor device.

FIG. 2 is a diagram illustrating a structure example of a semiconductor device.

FIG. 3A and FIG. 3B are diagrams each illustrating a structure example of a semiconductor device.

FIG. 4A to FIG. 4D are diagrams each illustrating a structure example of a semiconductor device.

FIG. 5A and FIG. 5B are diagrams each illustrating a structure example of a semiconductor device.

FIG. 6A to FIG. 6D are diagrams each illustrating a structure example of a semiconductor device.

FIG. 7A and FIG. 7B are diagrams each illustrating a structure example of the semiconductor device.

FIG. 8 is a diagram illustrating a structure example of a semiconductor device.

FIG. 9 is a diagram illustrating an example of a driving method of a semiconductor device.

FIG. 10 is a diagram illustrating a structure example of a semiconductor device.

FIG. 11A to FIG. 11C are diagrams each illustrating a structure example of a semiconductor device.

FIG. 12 is a diagram illustrating a structure example of a semiconductor device.

FIG. 13A to FIG. 13D are diagrams illustrating a structure example of a semiconductor device.

FIG. 14A and FIG. 14B are diagrams each illustrating a structure example of a semiconductor device.

FIG. 15 is a diagram illustrating a structure example of a semiconductor device.

FIG. 16 is a diagram illustrating a structure example of a semiconductor device.

FIG. 17A and FIG. 17B are diagrams each illustrating an example of an electronic component.

FIG. 18A and FIG. 18B are diagrams each illustrating an example of an electronic device, and FIG. 18C to FIG. 18E are diagrams each illustrating an example of a large computer.

FIG. 19 is a diagram illustrating an example of space equipment.

FIG. 20 illustrates an example of a storage system that can be used for a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be interpreted as being limited to the following description of the embodiments.

In the drawings, the size, the layer thickness, or the region is sometimes exaggerated for clarity. Therefore, the size, the layer thickness, or the region is not limited to the illustrated scale. Note that the drawings schematically illustrate ideal examples, and embodiments of the present invention are not limited to shapes, values, and the like illustrated in the drawings.

Unless otherwise specified, off-state current in this specification and the like refers to drain current of a transistor in an off state (also referred to as a non-conducting state or a cutoff state). Unless otherwise specified, an off state in an n-channel transistor refers to a state where voltage V_{gs} between its gate and source is lower than threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used for an active layer of a transistor, the metal oxide is referred to as an oxide semiconductor in some cases. That is, an OS transistor can also be referred to as a transistor including a metal oxide or an oxide semiconductor.

In this specification, “A is provided to be parallel to B” indicates a state where two surfaces (A and B) are positioned at an angle greater than or equal to −10° and less than or equal to 10°. Thus, the case where the angle is greater than or equal to −5° and less than or equal to 5°is also included. Furthermore, “A is provided to be roughly parallel to B” or “A is provided to be substantially parallel to B” indicates a state where two surfaces (A and B) are positioned at an angle greater than or equal to −30° and less than or equal to 30°. Furthermore, “A is provided perpendicular to B” indicates a state where two surfaces (A and B) are positioned at an angle greater than or equal to 80° and less than or equal to 100°. Thus, the case where the angle is greater than or equal to 85° and less than or equal to 95° is also included. Furthermore, “A is provided roughly perpendicular to B” or “A is provided substantially perpendicular to B” indicates a state where two surfaces (A and B) are positioned at an angle greater than or equal to 60° and less than or equal to 120°.

### Embodiment 1

In this embodiment, structure examples of a semiconductor device are described. The semiconductor device described in one embodiment of the present invention has a function of a memory device in which element layers each including a plurality of memory cells are stacked.

### Structure Example of Semiconductor Device

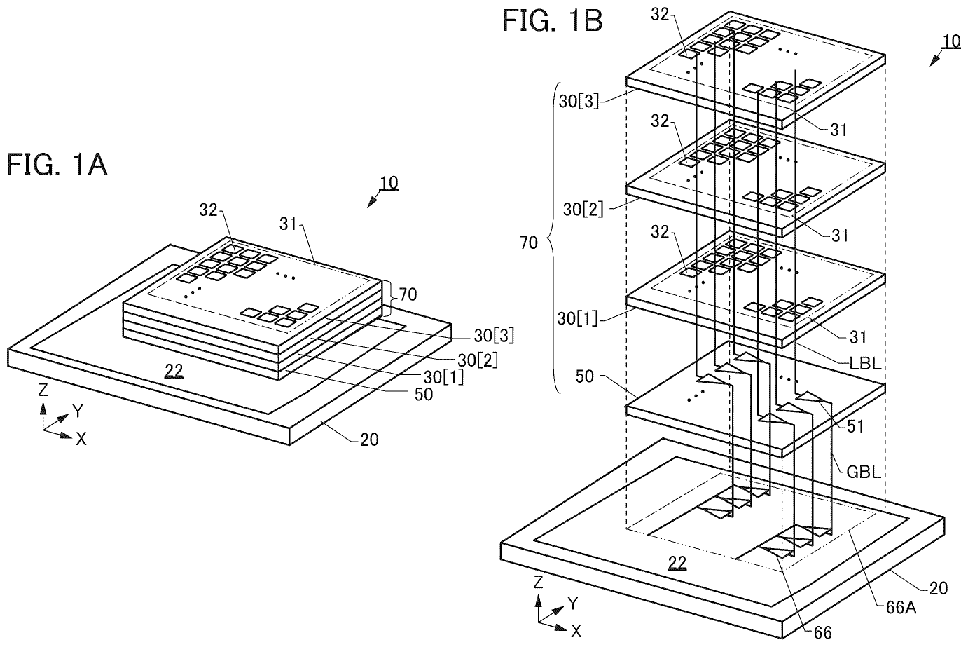

FIG. 1A is a perspective schematic view of a semiconductor device of one embodiment of the present invention. A semiconductor device 10 illustrated in FIG. 1A includes an element layer 20 and a plurality of element layers (an element layer 50 and element layers 30[1] to 30[3] in FIG. 1A as an example). FIG. 1B is a perspective view illustrating the element layer 20, the element layer 50 and the element layers 30[1] to 30[3] of the structure of FIG. 1A separately.

The element layer 20 is a layer including a transistor that includes silicon in a semiconductor layer including a channel formation region (a Si transistor). The element layer 20 is provided with a peripheral circuit 22 provided with a circuit for driving the element layer 50 and the element layers 30[1] to 30[3], for example. Note that the element layer 50 and the element layers 30[1] to 30[3] provided over the element layer 20 are collectively referred to as an element layer 70 in some cases.

The peripheral circuit 22 has a function of controlling amplifier circuits 51 included in the element layer 50 and controlling writing or reading of data to/from memory cells 32 included in a memory cell array 31 provided in each of the element layers 30[1] to 30[3]. The peripheral circuit 22 includes a circuit for driving the amplifier circuit 51 for amplifying a signal of a wiring LBL connected to the memory cell 32 and supplying the signal to a wiring GBL. The peripheral circuit 22 includes a plurality of driver circuits for driving signal lines such as word lines connected to the memory cells 32 provided in each of the element layers 30[1] to 30[3] and a control circuit.

For example, in the peripheral circuit 22, a region 66A where sense amplifiers 66 for reading data retained in the memory cells are provided is illustrated. The sense amplifier 66 is also referred to as a reading circuit. The sense amplifier 66 is a circuit for reading a signal of the wiring GBL connected to the amplifier circuit 51 to the outside.

The wiring LBL is provided between the memory cells 32 provided in the element layers 30[1] to 30[3] and the amplifier circuit 51 provided in the element layer 50. The wiring LBL is a wiring for electrical connection between the memory cells 32 and the amplifier circuit 51. The wiring LBL is referred to as a first bit line or a local bit line in some cases. Note that a wiring paired with the wiring LBL at the time of the reading operation or the like is referred to as a wiring LBLB.

The wiring GBL is provided between the amplifier circuit 51 provided in the element layer 50 and the sense amplifier 66 provided in the element layer 20. The wiring GBL is a wiring for electrical connection between the amplifier circuit 51 and the sense amplifier 66. The wiring GBL is referred to as a second bit line or a global bit line in some cases. Note that a wiring paired with the wiring GBL at the time of the reading operation or the like is referred to as a wiring GBLB.

In the element layer 20 including Si transistors in the structure of FIG. 1A and FIG. 1B, a CMOS circuit (Si CMOS circuit) can be formed. The peripheral circuit 22 can be formed with the CMOS circuit, which enables high-speed operation.

Note that for the semiconductor layer including a channel formation region in the Si transistor, a single crystal semiconductor, a polycrystalline semiconductor, a microcrystalline semiconductor, an amorphous semiconductor, or the like can be used alone or in combination. A semiconductor material is not limited to silicon, and germanium or the like can be used, for example. Alternatively, a compound semiconductor such as silicon germanium, silicon carbide, gallium arsenide, or a nitride semiconductor may be used.

The element layer 70 including the element layer 50 and the element layers 30[1] to 30[3] is an element layer including transistors using an oxide semiconductor in their channel formation regions (hereinafter OS transistors). The element layer 70 is stacked over the element layer 20. The Z direction in FIG. 1A and FIG. 1B is the direction perpendicular to a surface of a substrate provided with the element layer 20 is provided (a plane represented by the X direction and the Y direction) or the direction in which the element layer 70 is stacked over the element layer 20.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions orthogonal to each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction”in some cases.

FIG. 1A and FIG. 1B illustrate a state where the element layer 50 including the amplifier circuits 51 and the element layers 30[1] to 30[3] each including the memory cell array 31 are stacked over the element layer 20 in the semiconductor device 10. Providing the element layer 50 including the amplifier circuits 51 and the element layers 30[1] to 30[3] each including the memory cell array 31 over the element layer 20 can reduce the area occupied by the semiconductor device 10.

For example, the memory cell 32 is preferably a DOSRAM, which is a memory circuit including an OS transistor (also referred to as an “OS memory” in some cases). DOSRAM (registered trademark) is an abbreviation for “Dynamic Oxide Semiconductor Random Access Memory”. A DOSRAM refers to a RAM including a 1T (transistor) 1C (capacitor) memory cell. A DOSRAM is a DRAM formed using an OS transistor, and is a memory that temporarily stores information transmitted from the outside. A DOSRAM is a memory utilizing a low off-state current of an OS transistor.

In an OS transistor, a current that flows between a source and a drain in an off state, that is, an off-state current is extremely low. A DOSRAM enables long-term retention of electric charge corresponding to data stored in a capacitor (also referred to as a “cell capacitor” in some cases) by turning off an access transistor (by bringing the access transistor into a non-conduction state). For this reason, the refresh operation frequency of a DOSRAM can be lower than that of a DRAM formed using a transistor including silicon in a channel formation region (hereinafter also referred to as a “Si transistor”).

Note that examples of a metal oxide used for the OS transistor include indium oxide, gallium oxide, and zinc oxide. The metal oxide preferably contains two or three kinds selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin.

It is particularly preferable to use an oxide containing indium (In), gallium (Ga), and zinc (Zn) (also referred to as IGZO) for the metal oxide. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Alternatively, it is preferable to use an oxide containing indium (In), gallium (Ga), zinc (Zn), and tin (Sn) (also referred to as IGZTO).

The metal oxide used for the OS transistor may include two or more metal oxide layers with different compositions. For example, a stacked-layer structure of a first metal oxide layer having In: M:Zn=1:3:4 [atomic ratio] or a composition in the neighborhood thereof and a second metal oxide layer that is provided over the first metal oxide layer and has In:M:Zn=1:1:1 [atomic ratio] or a composition in the neighborhood thereof can be suitably used.

Alternatively, a stacked-layer structure of any one selected from indium oxide, indium gallium oxide, and IGZO, and any one selected from IAZO, IAGZO, and ITZO may be used, for example.

Note that the metal oxide used for the OS transistor preferably has crystallinity. Examples of an oxide semiconductor having crystallinity include a CAAC (c-axis aligned crystalline)-OS and an nc (nanocrystalline)-OS. When the oxide semiconductor having crystallinity is used, a highly reliable semiconductor device can be provided.

In addition, the OS transistor operates stably even in a high-temperature environment and has small fluctuation in characteristics. For example, the off-state current hardly increases even in a high-temperature environment. Specifically, the off-state current hardly increases even at an environment temperature higher than or equal to room temperature and lower than or equal to 200 ° C. In addition, the on-state current is less likely to decrease even in a high-temperature environment. Thus, a memory cell including the OS transistor operates stably and has high reliability even in a high-temperature environment.

When the memory cells 32 are provided by stacking OS transistors, the element layers 30[1] to 30[3] each including the memory cell array 31 and the element layer 50 including the amplifier circuits 51 can be stacked. When the element layers 30[1] to 30[3] are arranged in the direction perpendicular to the surface of the substrate provided with the element layer 20, the memory density of the memory cells 32 can be increased. Moreover, the element layers 30 can be formed by repeating the same formation process in the perpendicular direction. In the semiconductor device 10, the manufacturing cost of the element layers 30[1] to 30[3] can be reduced.

In FIG. 1A and FIG. 1B, the first element layer 30 is denoted by the element layer 30[1], the second element layer 30 is denoted by the element layer 30[2], and the third element layer 30 is denoted by the element layer 30[3]. Furthermore, a k-th element layer 30 (k is an integer greater than or equal to 1 and less than or equal to n) is denoted by an element layer 30[k], and an m-th element layer 30 is denoted by an element layer 30[m]. Note that in this embodiment and the like, a simple term “element layer 30” is sometimes used to describe matters related to all the m element layers 30 or matters common to the m element layers 30.

Stacking the element layers 30[1] to 30[3] each including the memory cell array 31 can increase the memory capacity per unit area. In a structure of a semiconductor device of one embodiment of the present invention, a trench capacitor (a deep-hole stacked capacitor) stacked with a transistor is used as the capacitor included in the memory cell 32, and the longitudinal direction of a semiconductor layer including a channel formation region included in the transistor (the direction in which current flows between the source and the drain of the transistor) is set in the direction perpendicular to the surface of the substrate provided with the element layer 20 (the Z direction in FIG. 1B). With this structure, the memory capacity per unit area can be increased and the capacitance value at the time of reading data from the memory cells 32 can be increased.

Meanwhile, as the number of element layers in which transistors and capacitors are stacked increases, the distance from the memory cell 32 to the peripheral circuit 22 becomes longer. That is, the wiring resistance and wiring capacitance of the wiring LBL functioning as a bit line connected to the memory cells 32 are increased. Due to the wiring resistance and wiring capacitance of the wiring LBL, a potential of the wiring LBL might decrease from a potential based on data retained in the memory cells 32, which might impair the reliability of data to be read.

In order to read data retained in the memory cell 32 without decreasing the potential, a structure in which the amplifier circuit 51 is provided between the sense amplifier 66 and the wiring LBL as in one embodiment of the present invention is effective. The amplifier circuit 51 has a function of transmitting a signal corresponding to the potential of the wiring LBL to the wiring GBL electrically connected to the sense amplifier 66. With this structure, the semiconductor device can have high reliability of data to be read even when the element layers 30[1] to 30[3] each including the memory cell array 31 are added.

Like the transistor included in the memory cell 32, the transistor included in the amplifier circuit 51 included in the element layer 50 is preferably an OS transistor. Meanwhile, the amplifier circuits 51 can be provided at lower density than the number of memory cells 32. Thus, in the structure of the semiconductor device of one embodiment of the present invention, the longitudinal direction of a semiconductor layer including a channel formation region in a transistor included in the amplifier circuit 51 can be parallel to the surface of the substrate provided with the element layer 20. With this structure, a first gate that controls the electrical characteristics of a transistor (also referred to as a “front gate” or simply a “gate”) and a second gate (also referred to as a “back gate”) can be provided. The first gate and the second gate have regions overlapping with each other with a semiconductor layer therebetween. The second gate has a function of controlling the threshold voltage of the transistor, for example.

Note that in a transistor included in the amplifier circuit 51, a signal for controlling the threshold voltage of a transistor supplied to the second gate is preferably controlled in accordance with the temperature. For example, in the case where the temperature is high in the semiconductor device, a structure in which the voltage applied to the second gate is controlled such that the threshold voltage shifted to the negative side because of the high temperature is shifted in the positive direction is effective. In the case where the temperature is low in the semiconductor device, a structure in which the voltage applied to the second gate is controlled such that the threshold voltage shifted to the positive side because of the low temperature is shifted in the negative direction is effective.

Note that in the element layer 20 provided with the peripheral circuit 22, the region 66A provided with the sense amplifiers 66 is preferably provided in a region overlapping with the element layer 70. With this structure, the wiring LBL, which is a path from the memory cell 32 to the amplifier circuit 51, or the wiring GBL, which is a path from the amplifier circuit 51 to the sense amplifier 66 can be shortened. A difference in the length of the path of the wiring LBL and the wiring GBL causes differences in the parasitic capacitance and the parasitic resistance, which leads to a difference in signal delay and a difference in power consumption. Thus, in the structure of FIG. 1A and FIG. 1B, data can be read from each of the memory cell arrays 31 of the element layers 30[1] to 30[3] with the same level of signal delay and power consumption.

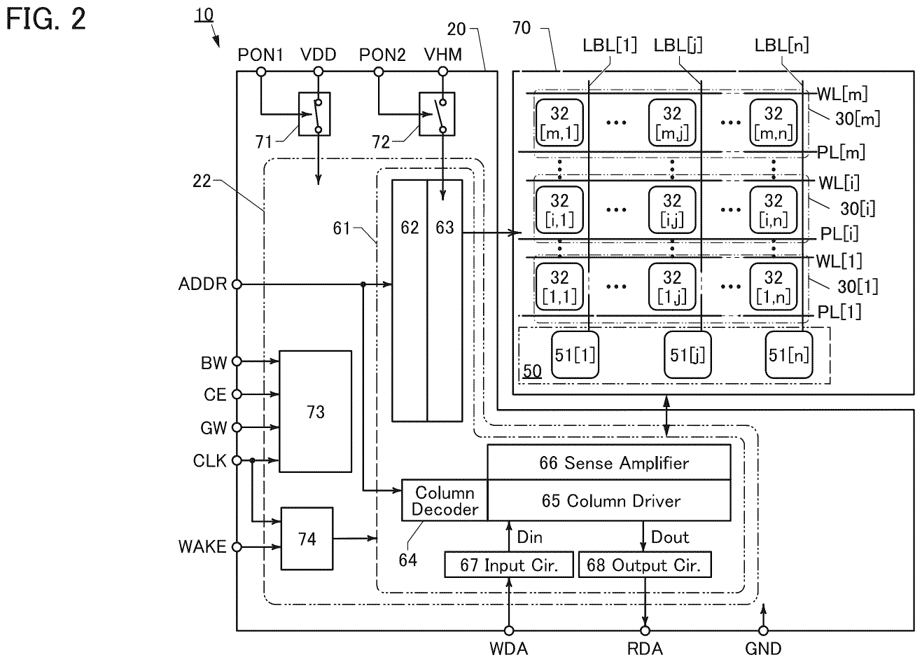

FIG. 2 is a block diagram illustrating a structure example of the semiconductor device 10 of one embodiment of the present invention. The semiconductor device 10 illustrated in FIG. 2 includes the element layer 20 and the multilayer element layer 70. The multilayer element layer 70 includes the stacked element layers 30[1] to 30[m] and the element layer 50 including the amplifier circuits 51.

FIG. 2 illustrates an example of the element layer 70 including m element layers 30 including n memory cells 32 (m and n are each an integer greater than or equal to 2), that is, the element layer 70 including a plurality of memory cells 32 in m rows and n columns. The amplifier circuit 51 is provided for each wiring LBL functioning as a bit line connected to the memory cells 32, for example. FIG. 2 illustrates an example in which a plurality of amplifier circuits 51 (an amplifier circuit 51[1] to an amplifier circuit 51[n]) are provided to correspond to n wirings LBL.

In FIG. 2, the memory cell 32 in the first row and the first column is denoted as a memory cell 32[1,1], and the memory cell 32 in the m-th row and the n-th column is denoted as a memory cell 32[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 32 in the i-th row and the j-th column is denoted as a memory cell 32[i,j]. Note that in this embodiment and the like, “i+a” (a is a positive or negative integer) is not below 1 and does not exceed m. Similarly, “j+a” is not below 1 and does not exceed n.

The element layers 30[1] to 30[m] include m wirings WL extending in the row direction, m wirings PL extending in the row direction, and the n wirings LBL extending in the column direction. In this embodiment and the like, a first wiring WL (provided in the first row) is denoted as a wiring WL[1], and an m-th wiring WL (provided in the m-th row) is denoted as a wiring WL[m]. Similarly, a first wiring PL (provided in the first row) is denoted as a wiring PL[1], and an m-th wiring PL (provided in the m-th row) is denoted as a wiring PL[m]. Similarly, a first wiring LBL (provided in the first column) is denoted as a wiring LBL[1], and an n-th wiring LBL (provided in the n-th column) is denoted as a wiring LBL[n].

The plurality of memory cells 32 provided in the i-th row are electrically connected to the wiring WL in the i-th row (wiring WL[i]) and the wiring PL in the i-th row (wiring PL[i]). The plurality of memory cells 32 provided in the j-th column are electrically connected to the wiring LBL in the j-th column (wiring LBL[j]).

The wiring LBL functions as a bit line for writing and reading data. The wiring WL functions as a word line for controlling the on and off state (conduction and non-conduction state) of the access transistor serving as a switch. The wiring PL has a function of a constant potential line connected to a capacitor.

The memory cell 32 included in each of the element layers 30[1] to 30[m] is connected to the amplifier circuit 51 through the wiring LBL. The wiring LBL can be provided in the directions perpendicular to and parallel to the surface of the substrate provided with the element layer 20. Since the wiring LBL provided to extend from the memory cells 32 included in the element layers 30[1] to 30[m] is provided in as well as the direction parallel to, the direction perpendicular to the surface of the substrate, the length of the wiring between the element layers 30 and the amplifier circuit 51 can be shortened. Accordingly, a signal transmission distance between the two circuits connected to the bit line can be shortened, and the resistance and parasitic capacitance of the bit line can be significantly reduced; hence, power consumption and signal delay can be reduced. Moreover, operation is possible even when the capacitance of the capacitors included in the memory cells 32 is reduced.

The amplifier circuit 51 has functions of amplifying data potentials retained in the memory cells 32 and outputting the amplified data potentials to the sense amplifier 66 included in the element layer 20 through the wiring GBL (not illustrated). With this structure, a slight difference in the potential of the wiring LBL can be amplified at the time of data reading. Like the wiring LBL, the wiring GBL can be provided in the directions perpendicular to and parallel to the surface of the substrate provided with the element layer 20. Since the wiring LBL provided to extend from the memory cells 32 included in the element layers 30[1] to 30[m] and the wiring GBL are provided in the directions perpendicular to and parallel to the surface of the substrate, the length of the wiring between the amplifier circuit 51 and the sense amplifier 66 can be shortened. Accordingly, a signal transmission distance between the two circuits connected to the wiring GBL can be shortened, and the resistance and parasitic capacitance of the wiring GBL can be significantly reduced; hence, power consumption and signal delay can be reduced.

The wiring LBL is provided in contact with a region functioning as the source or the drain in the semiconductor layer of the transistor included in the memory cell 32. Alternatively, the wiring LBL is provided in contact with a conductor provided in contact with the region functioning as the source or the drain in the semiconductor layer of the transistor included in the memory cell 32. That is, the wiring LBL is a wiring for electrically connecting one of a source and a drain of the transistor included in the memory cell 32 in each element layer 30 to the amplifier circuit 51.

The multilayer element layer 70 can be provided to be over and overlap with the element layer 20. Providing the element layer 20 and the multilayer element layer 70 to overlap with each other can shorten a signal transmission distance between the element layers 30 and the element layer 50 and between the element layer 20 and the element layer 50. Thus, the resistance and parasitic capacitance between the element layers are reduced, so that power consumption and signal delay can be reduced. In addition, the semiconductor device 10 can be downsized.

When the amplifier circuit 51 is formed using OS transistors like the transistor included in the memory cell 32 of the DOSRAM, the amplifier circuit 51 can be provided at any desired position, e.g., over a circuit using Si transistors, as in the element layers 30[1] to 30[m]; thus, integration can be easily performed. With the structure in which a signal is amplified by the amplifier circuit 51, a circuit in a subsequent stage, such as the sense amplifier 66, can be downsized; hence, the semiconductor device 10 can be downsized.

The element layer 20 includes a PSW 71 (power switch) and a PSW 72 in addition to the peripheral circuit 22. The peripheral circuit 22 includes a driver circuit 61, a control circuit 73, and a voltage generation circuit 74.

In the semiconductor device 10, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 73.

The control circuit 73 is a logic circuit having a function of controlling the overall operation of the semiconductor device 10. For example, the control circuit performs logical operation on the signal CE, the signal GW, and the signal BW to determine an operation mode (e.g., write operation or read operation) of the semiconductor device 10. Alternatively, the control circuit 73 generates a control signal for the driver circuit 61 so that the operation mode is executed.

The voltage generation circuit 74 has a function of generating a negative voltage. The signal WAKE has a function of controlling the input of the signal CLK to the voltage generation circuit 74. For example, when an H-level signal is supplied as the signal WAKE, the signal CLK is input to the voltage generation circuit 74, and the voltage generation circuit 74 generates a negative voltage.

The driver circuit 61 is a circuit for writing and reading data to/from the memory cells 32. Moreover, the driver circuit 61 is a circuit that outputs various signals for controlling the amplifier circuits 51. The driver circuit 61 includes a row decoder 62, a column decoder 64, a row driver 63, a column driver 65, an input circuit 67 (Input Cir.), an output circuit 68 (Output Cir.), and the sense amplifier 66 described above.

The row decoder 62 and the column decoder 64 have a function of decoding the signal ADDR. The row decoder 62 is a circuit for specifying a row to be accessed, and the column decoder 64 is a circuit for specifying a column to be accessed. The row driver 63 has a function of selecting the wiring WL specified by the row decoder 62. The column driver 65 has a function of writing data to the memory cells 32, a function of reading data from the memory cells 32, a function of retaining the read data, and the like.

The input circuit 67 has a function of retaining the signal WDA. Data retained by the input circuit 67 is output to the column driver 65. Data output from the input circuit 67 is data (Din) to be written to the memory cells 32. Data (Dout) read from the memory cells 32 by the column driver 65 is output to the output circuit 68. The output circuit 68 has a function of retaining Dout. Moreover, the output circuit 68 has a function of outputting Dout to the outside of the semiconductor device 10. Data output from the output circuit 68 is the signal RDA.

The PSW 71 has a function of controlling the supply of VDD to the peripheral circuit 22. The PSW 72 has a function of controlling the supply of VHM to the row driver 63. Here, in the semiconductor device 10, a high power supply voltage is VDD and a low power supply voltage is GND (a ground potential). In addition, VHM is a high power supply voltage used to set the word line at high level and is higher than VDD. The on/off state of the PSW 71 is controlled by the signal PON1, and the on/off state of the PSW 72 is controlled by the signal PON2. The number of power domains to which VDD is supplied is one in the peripheral circuit 22 in FIG. 2 but can be more than one. In such a case, a power switch is provided for each power domain.

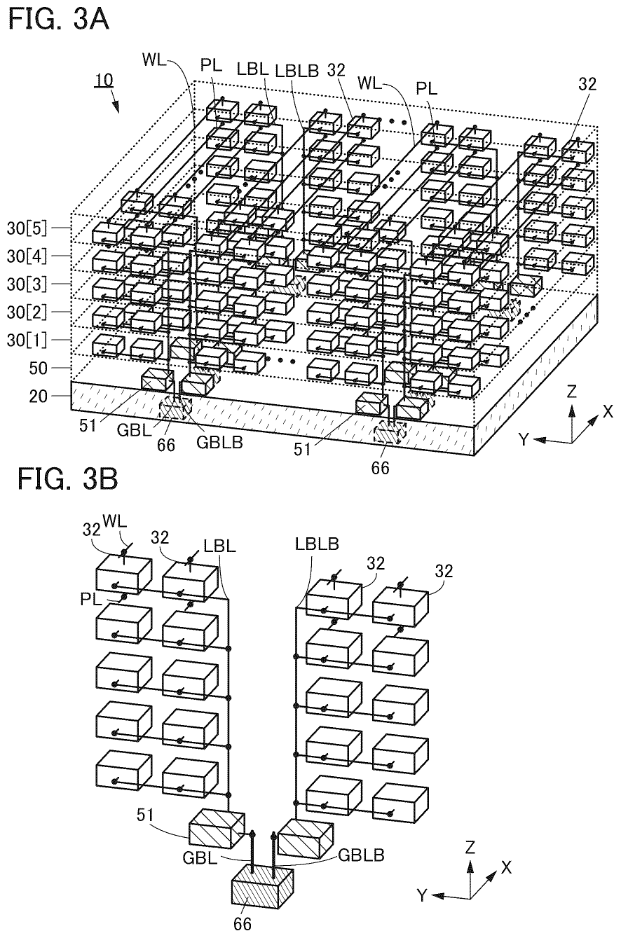

The element layers 30[1] to 30[m] and the element layer 50 can be provided to be over and overlap with the element layer 20. FIG. 3A is a perspective view of the semiconductor device 10 in which five element layers 30[1] to 30[5] (m=5) and the element layer 50 are provided to be over and overlap with the element layer 20.

In FIG. 3A, the element layer 30 provided in the first layer is denoted as the element layer 30[1], the element layer 30 provided in the second layer is denoted as the element layer 30[2], and the element layer 30 provided in the fifth layer is denoted as the element layer 30[5]. FIG. 3A illustrates the wiring WL and the wiring PL, which are provided to extend in the X direction, the wiring LBL, the wiring LBLB paired with the wiring LBL, the wiring GBL and the wiring GBLB paired with the wiring GBL, which are provided to extend in the Z direction (the direction perpendicular to the surface of the substrate provided with the driver circuit). For easy viewing of the drawing, some of the wirings WL and the wirings PL included in the element layers 30 are not illustrated.

FIG. 3B is a schematic view illustrating a structure example of the sense amplifier 66 connected to the wiring GBL, the amplifiers circuit 51 each connected to the wiring LBL (or the wiring LBLB) and the wiring GBL, and the memory cells 32 included in the element layers 30[1] to 30[5] connected to the wiring LBL (or the wiring LBLB), which are illustrated in FIG. 3A. Note that a structure in which the plurality of memory cells (memory cells 32) are electrically connected to one wiring LBL (or one wiring LBLB) is also referred to as “memory string”. In the drawings, the wiring GBL and the wiring GBLB are sometimes represented by bold lines for increasing visibility.

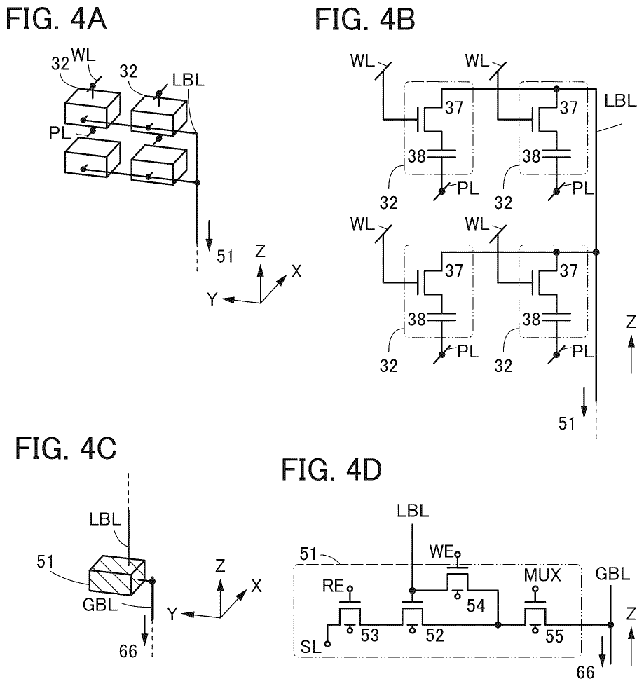

FIG. 4A illustrates the structure of the memory cell 32 extracted to be illustrated in FIG. 3B and connected to the wiring LBL, and FIG. 4B illustrates an example of a circuit structure thereof. The memory cell 32 includes a transistor 37 and a capacitor 38. As for the transistor 37, the capacitor 38, and the wirings (e.g., the wirings LBL and WL), for example, the wiring LBL[1] and the wiring WL[1] are referred to as the wiring LBL and the wiring WL, respectively, in some cases.

In the memory cell 32, one of a source and a drain of the transistor 37 is connected to the wiring LBL. The other of the source and the drain of the transistor 37 is connected to one electrode of the capacitor 38. The other electrode of the capacitor 38 is connected to the wiring PL. The gate of the transistor 37 is connected to the wiring WL. The wiring PL is a wiring for supplying a fixed potential for retaining a potential of the capacitor 38.

In one embodiment of the present invention, the OS transistors are stacked, and the wiring LBL functioning as a bit line is provided in the direction perpendicular to the surface of the substrate provided with the element layer 20. In addition, the transistor 37 and the capacitor 38 included in the memory cell 32 are arranged in the direction perpendicular to the surface of the substrate provided with the element layer 20. When the elements and the wirings are provided in the direction perpendicular to the surface of the substrate, the length of the wirings between the element layers can be shortened and the density of elements provided per unit area can be increased. Thus, the memory device can have excellent memory capacity and excellent in reducing power consumption.

In addition, in the structure of the semiconductor device of one embodiment of the present invention, the capacitor included in the memory cell 32 is a trench capacitor (a deep-hole stacked capacitor) stacked with a transistor, and the semiconductor layer including the channel formation region of the transistor is provided in the direction perpendicular to the surface of the substrate provided with the element layer 20. FIG. 4A illustrates a structure in which the direction of current flowing between the source and the drain of the transistor 37 is parallel to the Z direction. With this structure, the memory capacity per unit area can be increased and the capacitance value at the time of reading data from the memory cells 32 can be increased.

FIG. 4C illustrates the structure of the amplifier circuit 51, which is extracted to be illustrated in FIG. 3B and connected to the wiring LBL and the wiring GBL, and FIG. 4D illustrates an example of a circuit structure thereof. The amplifier circuit 51 includes a transistor 52 to a transistor 55, which are described in detail later.

In one embodiment of the present invention, the OS transistors are stacked, and the wiring LBL and the wiring GBL functioning as bit lines are provided in the direction perpendicular to the surface of the substrate provided with the element layer 20.

In addition, in the structure of the semiconductor device of one embodiment of the present invention, the semiconductor layer including the channel formation region of the transistor included in the amplifier circuit 51 can be provided in the direction parallel to the surface of the substrate provided with the element layer 20. FIG. 4D illustrates a structure in which the direction of current flowing between the source and the drain of the transistor 37 is perpendicular to the Z direction. With this structure, the second gate can be provided in addition to the first gate that controls the electrical characteristics of a transistor.

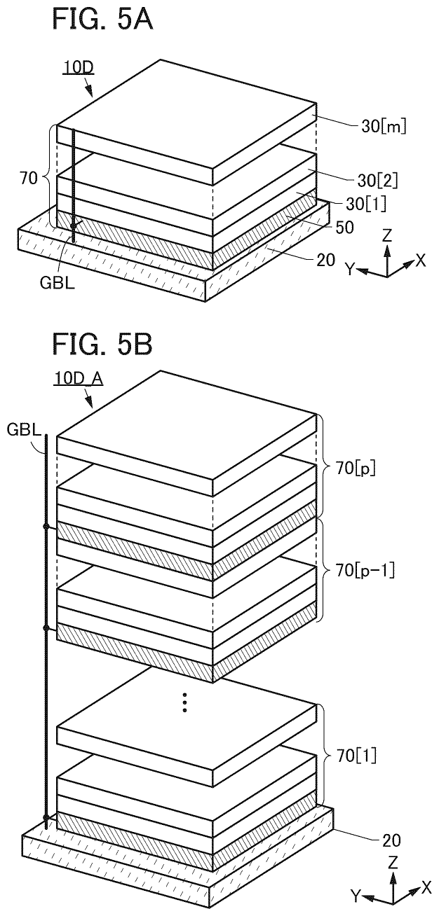

The wiring GBL illustrated in FIG. 3B is provided to electrically connect the amplifier circuit 51 and the sense amplifier 66. FIG. 5A is a schematic view of a semiconductor device 10D including the element layer 50 including the amplifier circuits 51 illustrated in FIG. 3B and the multilayer element layer 70 including the element layers 30[1] to 30[m] as a repeating unit. Note that although FIG. 5A illustrates one wiring GBL, the wirings GBL are provided as appropriate depending on the number of amplifier circuits 51 provided in the element layer 50.

The multilayer element layer 70 including the amplifier circuit 51 and the element layers 30[1] to 30[m] may be stacked. A semiconductor device 10D_A of one embodiment of the present invention can include multilayer element layers 70[1] to 70[p] (pis an integer greater than or equal to 2) as illustrated in FIG. 5B. The wiring GBL is connected to the element layer 50 included in the multilayer element layer 70. The wirings GBL are provided as appropriate depending on the number of amplifier circuits 51.

In one embodiment of the present invention, OS transistors are stacked, and the wiring LBL and the wiring GBL functioning as bit lines are provided in the direction perpendicular to the surface of the substrate provided with the element layer 20. When the wiring that is provided to extend from the element layer 30 and functions as a bit line is provided in the direction perpendicular to the surface of the substrate, the length of the wiring between the element layer 30 and the element layer 20 can be shortened. Thus, the parasitic capacitance of the bit line can be significantly reduced.

In one embodiment of the present invention, the element layer 50 including the amplifier circuit 51 having functions of amplifying and outputting a data potential retained in the memory cell 32 is provided in the layer where the element layer 30 is provided. With this structure, a slight difference in the potential of the wiring LBL functioning as a bit line can be amplified at the time of data reading to drive the sense amplifier 66 included in the element layer 20. A circuit such as the sense amplifier can be downsized, so that the semiconductor device 10 can be downsized. Moreover, operation is possible even when the capacitance of the capacitors included in the memory cells 32 is reduced.

### Structure Example of Memory Cell 32, Amplifier Circuit 51, and Sense Amplifier 66

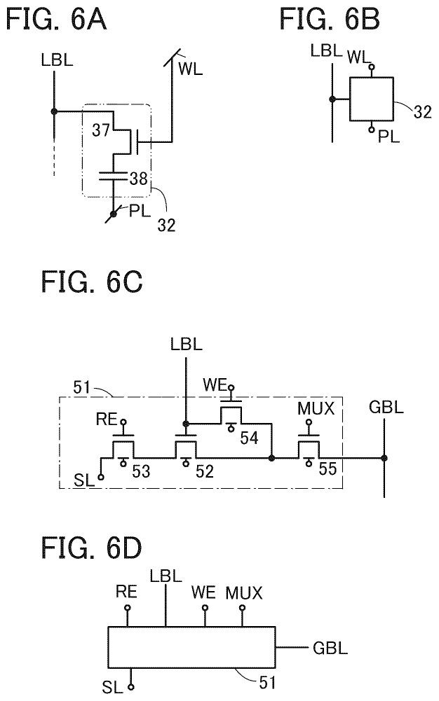

FIG. 6A and FIG. 6B illustrate a circuit diagram corresponding to the memory cell 32 illustrated in FIG. 4B and the like and a diagram illustrating a circuit block corresponding to the circuit diagram. As illustrated in FIG. 6A and FIG. 6B, the memory cell 32 is sometimes illustrated as a block in the drawings and the like.

FIG. 6C and FIG. 6D illustrate a circuit diagram corresponding to the amplifier circuit 51 illustrated in FIG. 4D and the like and a diagram illustrating a circuit block corresponding to the circuit diagram, respectively. As illustrated in FIG. 6C and FIG. 6D, the amplifier circuit 51 including the transistors 52 to 55 is sometimes illustrated as a block of the amplifier circuit 51 in the drawings and the like. The amplifier circuit 51 has functions of amplifying the potential of the wiring LBL and transmitting the amplified potential to the wiring GBL. Moreover, the amplifier circuit 51 can perform operation in which a fluctuation in the threshold voltage of the transistor 52 is corrected by providing a correction period. Signals WE, RE, and MUX are control signals for controlling the amplifier circuit 51. A wiring SL is a wiring supplying a constant potential.

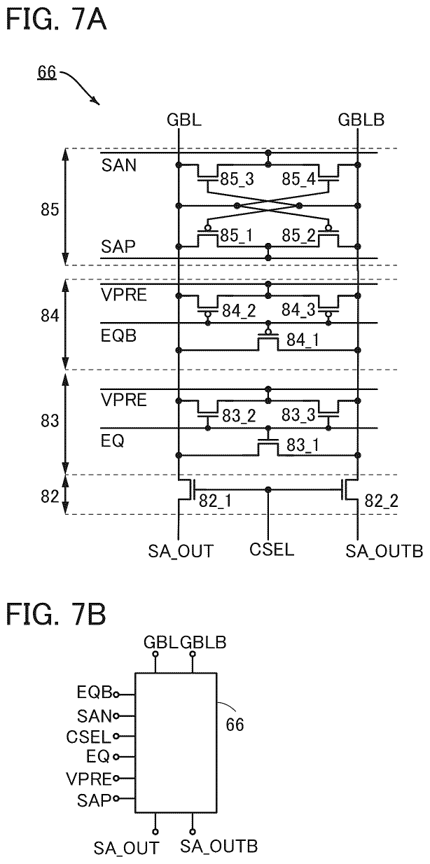

FIG. 7A illustrates a circuit structure example of the sense amplifier 66 illustrated in FIG. 3A, FIG. 3B, and the like. A switch circuit 82, a precharge circuit 83, a precharge circuit 84, and an amplifier circuit 85 are illustrated in the sense amplifier 66. In addition, a wiring SA_OUT and a wiring SA_OUTB, each of which output a read signal, are illustrated in addition to the wiring GBL and the wiring GBLB.

The switch circuit 82 includes, for example, n-channel transistors 82_1 and 82_2, as illustrated in FIG. 7A. The transistors 82_1 and 82_2 switch a conduction state between the wiring pair of the wiring SA_OUT and the wiring SA_OUTB and between the wiring pair of the wiring GBL and the wiring GBLB in response to a signal CSEL.

The precharge circuit 83 is formed using n-channel transistors 83_1 to 83_3 as illustrated in FIG. 7A. The precharge circuit 83 is a circuit for precharging the wiring BL and the wiring BLB to an intermediate potential VPRE corresponding to half of the potential VDD in response to a signal EQ.

The precharge circuit 84 is formed using p-channel transistors 84_1 to 84_3 as illustrated in FIG. 7A. The precharge circuit 84 is a circuit for precharging the wiring BL and the wiring BLB to the intermediate potential VPRE corresponding to half of the potential VDD in response to a signal EQB.

A sense amplifier 85 is formed using p-channel transistors 85_1 and 85_2 and n-channel transistors 85_3 and 85_4 that are connected to a wiring SAP or a wiring SAN, as illustrated in FIG. 7A. The wiring SAP or the wiring SAN is a wiring having a function of supplying VDD or VSS. The transistors 85_1 to 85_4 are transistors that form an inverter loop.

FIG. 7B illustrates a circuit block corresponding to the sense amplifier 66 illustrated in FIG. 7A and the like. As illustrated in FIG. 7B, the sense amplifier 66 is sometimes illustrated as a block in the drawings and the like.

### Operation Example of Memory Cell 32, Amplifier Circuit 51, and Sense Amplifier 66

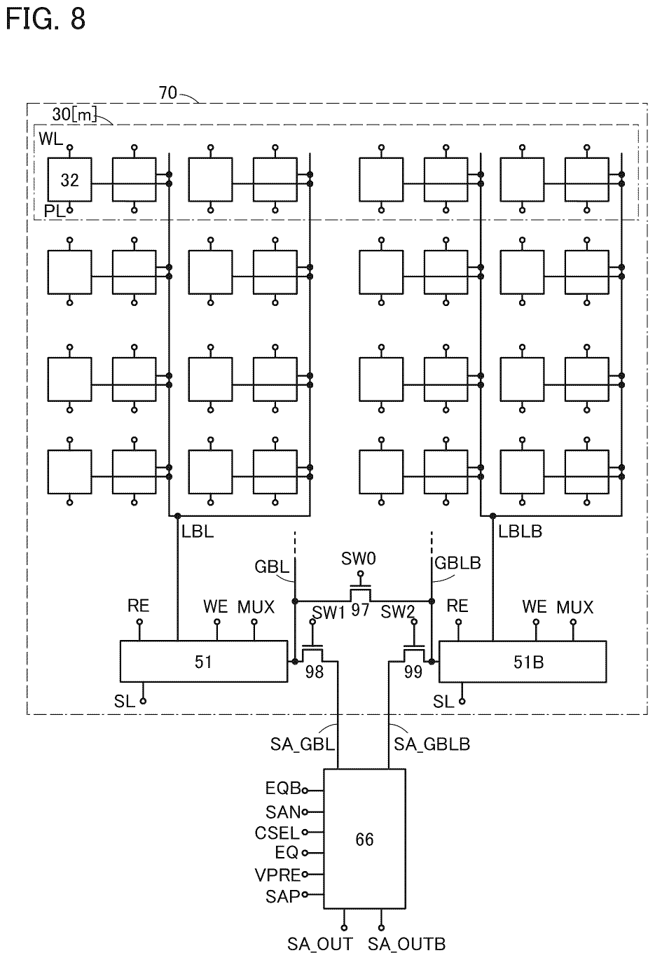

FIG. 8 is a circuit diagram for describing an operation example of the semiconductor device 10 in FIG. 2. In FIG. 8, the circuit blocks illustrated in FIG. 6A to FIG. 6D, FIG. 7A, and FIG. 7B are used.

As illustrated in FIG. 8, the stacked element layer 70 including the element layer 30[m] includes the memory cells 32. The memory cells 32 are connected to the wiring LBL and the wiring LBLB, which are paired together. The memory cells 32 connected to the wiring LBL are memory cells to/from which data is written or read. The wiring LBLB is a local bit line to be precharged, and the memory cells 32 connected to the wiring LBLB continue retaining data.

The wiring LBL is electrically connected to the wiring GBL through the amplifier circuit 51. The wiring LBLB is electrically connected to the wiring GBLB through an amplifier circuit 51B.

A transistor 97 functions as a switch for switching a conduction state between the wiring GBL and the wiring GBLB. The on/off state of the transistor 97 is switched by a signal SWO.

A transistor 98 functions as a switch for switching a conduction state between the wiring GBL and a wiring SA_GBL on the sense amplifier 66 side. The on/off state of the transistor 98 is switched by a signal SW1. The wiring SA_GBL is electrically connected to the wiring GBL through the transistor 98 and can be regarded as part of the wiring GBL.

A transistor 99 functions as a switch for switching a conduction state between the wiring GBLB and a wiring SA_GBLB on the sense amplifier 66 side. The on/off state of the transistor 99 is switched by a signal SW2. The wiring SA_GBLB is electrically connected to the wiring GBLB through the transistor 99 and can be regarded as part of the wiring GBLB.

Note that the transistors 97 to 99 preferably have the same structure as the transistors included in the amplifier circuit 51. That is, in each of the transistors 97 to 99, the direction of current flowing between a source and a drain is perpendicular to the Z direction, as in the transistors 52 to 55. Although not illustrated, the first gate and the second gate can be provided in each of the transistors 97 to 99.

As illustrated in FIG. 8, the memory cells 32 can be connected to the amplifier circuit 51 and the sense amplifier 66 through the wiring LBL and the wiring GBL provided in the perpendicular direction, i.e., in the shortest distance. Even with the addition of the element layer 50 including the transistors that constitute the amplifier circuit 51, a reduction in the load of the wiring LBL can shorten the write time or facilitate data reading.

As illustrated in FIG. 8, transistors included in the amplifier circuits 51 and 51B are controlled in accordance with the signals WE, RE, and MUX. The transistors can output the potential of the wiring LBL to the sense amplifier 66 through the wiring in accordance with the signals. The amplifier circuits 51 and 51B can each function as a sense amplifier that is formed using OS transistors. With this structure, a slight difference in the potential of the wiring LBL can be amplified at the time of reading to drive the sense amplifier 66.

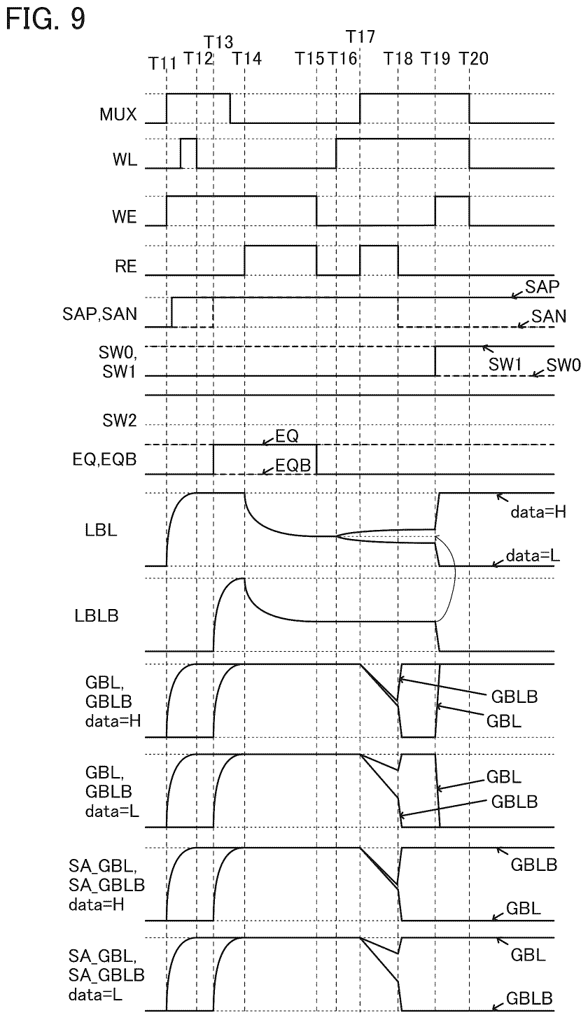

FIG. 9 is a timing chart for describing the operation of the circuit diagram illustrated in FIG. 8 and an operation example of the memory cell 32, the amplifier circuit 51, and the sense amplifier 66 is described. Note that the timing chart in FIG. 9 separately illustrates the case where data is at H level (data=H) and the case where data is at L level (data=L), for the wiring pair of the wiring SA_GBL and the wiring SA_GBLB and the wiring pair of the wiring GBL and the wiring GBLB.

In the timing chart in FIG. 9, Time T11 to Time T13 correspond to a period for data writing. Time T13 to Time T16 correspond to a correction period. Time T16 to Time T18 correspond to a period for data reading.

At Time T11, a signal MUX and a signal WE are set to H level. The signals SW1 and SW2 are set to H level, and the signal SWO is set to L level. Then, the power supply voltages (VDD and VSS) are applied to the wirings SAP and SAN, thereby charging one of the wiring SA_GBL and the wiring SA_GBLB, which form the wiring pair, and one of the wiring GBL and the wiring GBLB, which form the wiring pair. The potential of the wiring LBL increases. The potential of the wiring WL is set to H level, and the potential applied to the wiring LBL (H level in the case of FIG. 9) is written to the memory cell 32.

At Time T12, the potential of the wiring WL is set to L level. Data is retained in the memory cell 32.

At Time T13, both the wirings SAP and SAN are set to VDD, and the signals EQ and EQB are inverted, whereby both the wiring pair of the wiring SA_GBL and the wiring SA_GBLB and the wiring pair of the wiring GBL and the wiring GBLB are set to H level. The wiring LBLB is precharged to an H-level potential. After that, the signal MUX is set to L level. The signal WE may also be set to L level.

At Time T14, a signal RE and a signal WE are set to H level. The potential of the wiring LBL and the potential of the wiring LBLB decrease by discharge through the transistor 52. This discharge stops when the voltage between the gate and the source of the transistor 52 becomes equal to the threshold voltage of the transistor 52.

At Time T15, both the signal WE and the signal RE are set to L level. A potential corresponding to the threshold voltage of the transistor 52 is retained in the wiring LBL and the wiring LBLB. The signals EQ and EQB are inverted again, and precharge is stopped. That is, the wiring pair of the wiring SA_GBL and the wiring SA_GBLB and the wiring pair of the wiring GBL and the wiring GBLB are brought into an electrically floating state, or a floating state.

At Time T16, the wiring WL is set to H level to perform charge sharing. The potential of the wiring LBL varies in accordance with the data written to the memory cell 32. When H-level data is written to the memory cell 32, the potential of the wiring LBL increases, and when L-level data is written to the memory cell 32, the potential of the wiring LBL decreases. Meanwhile, the potential of the wiring LBLB does not vary because the charge sharing by the operation of the wiring WL is not performed in the wiring LBLB.

At Time T17, the signal RE and the signal MUX are set to H level, whereby current flows through the transistor 52 included in the amplifier circuit 51 and the transistor 52 included in the amplifier circuit 51B in accordance with the potentials of the wiring LBL and the wiring LBLB. Since the potentials of the wiring LBL and the wiring LBLB are different from each other, a difference occurs between current flowing through the transistor 52 included in the amplifier circuit 51 and current flowing through the transistor 52 included in the amplifier circuit 51B. The difference in the current corresponds to the potential of the wiring LBL varying depending on the charge sharing, i.e., data read from the memory cell 32. Thus, the data of the memory cell 32 can be converted into the amount of changes in the potentials of the wiring pair of the wiring SA_GBL and the wiring SA_GBLB and the wiring pair of the wiring GBL and the wiring GBLB, as illustrated in FIG. 9.

At Time T18, the signal RE is set to L level. Then, the power supply voltages (VDD and VSS) are applied to the wirings SAP and SAN, whereby the sense amplifier 66 is operated. When the sense amplifier 66 operates, the potentials of the wiring pair of the wiring SA_GBL and the wiring SA_GBLB and the wiring pair of the wiring GBL and the wiring GBLB are determined.

At Time T19, the signal SW0 is set to H level and the signal SW1 is set to L level, and the potentials of the wiring pair of the wiring GBL and the wiring GBLB are switched in accordance with the read data. Specifically, when the data is at H level, the potentials of the wiring GBL and the wiring GBLB, which form the wiring pair, are both switched to H level. When the data is at L level, the potentials of the wiring GBL and the wiring GBLB, which form the wiring pair, are both switched to L level. By setting the wiring WL to H level in this state, the voltage corresponding to the logic of the read data can be written back to the memory cell 32.

At Time T20, the potential of the wiring WL is set to L level, and the signal MUX and the signal WE are set to L level. In the memory cell 32, data corresponding to the logic of the read data can be refreshed.

Note that in the semiconductor device 10 of one embodiment of the present invention, the element layers 30 including the memory cells 32 are stacked. In this structure, the wiring LBL can be shortened and the capacitance of the capacitor 38 in the memory cell 32 can be reduced.

In the semiconductor device of one embodiment of the present invention, OS transistors with an extremely low off-state current are used as the transistors provided in the element layers 30. The OS transistors can be stacked over the substrate where the element layer 20 provided with Si transistors is provided. Thus, the OS transistors can be formed in the perpendicular direction by repeating the same manufacturing process, so that manufacturing cost can be reduced. Furthermore, in one embodiment of the present invention, the memory density can be increased by arranging the transistors included in the memory cells 32 in not the plane direction but the perpendicular direction, whereby the semiconductor device can be downsized.

In addition, one embodiment of the present invention is provided with the element layer 50 including the amplifier circuits 51. In the amplifier circuit 51, the wiring LBL is connected to the gate of the transistor 52; thus, the transistor 52 can function as an amplifier. With this structure, a slight difference in the potential of the wiring LBL can be amplified at the time of reading to drive the sense amplifier 66 formed using Si transistors. Since the circuit such as the sense amplifier 66 formed using Si transistors can be downsized, the semiconductor device can be downsized. Moreover, operation is possible even when the capacitance of the capacitors 38 included in the memory cells 32 is reduced.

In addition, in the structure of the semiconductor device of one embodiment of the present invention, the capacitor included in the memory cell 32 is a trench capacitor (a deep-hole stacked capacitor) stacked with a transistor, and the semiconductor layer including the channel formation region of the transistor is provided in the direction perpendicular to the surface of the substrate provided with the element layer 20. With this structure, the memory capacity per unit area can be increased and the capacitance value at the time of reading data from the memory cell 32 can be increased.

In addition, in the structure of the semiconductor device of one embodiment of the present invention, the semiconductor layer including the channel formation region of the transistor included in the amplifier circuit 51 can be provided in the direction parallel to the surface of the substrate provided with the element layer 20. FIG. 4D illustrates a structure in which the direction of current flowing between a source and a drain of each of the transistors 52 to 55 is perpendicular to the Z direction. With this structure, the second gate can be provided in addition to the first gate that controls the electrical characteristics of a transistor.

### Schematic Cross-Sectional View of Memory Cell 32, Amplifier Circuit 51 and Sense Amplifier 66

A structure example of a schematic cross-sectional view of transistors that can be used for the above-described semiconductor device is described. As an example, a structure in which transistors having different electrical characteristics are stacked will be described. With this structure, the design flexibility of a semiconductor device can be increased. In addition, stacking transistors having different electrical characteristics can increase the integration degree of the semiconductor device.

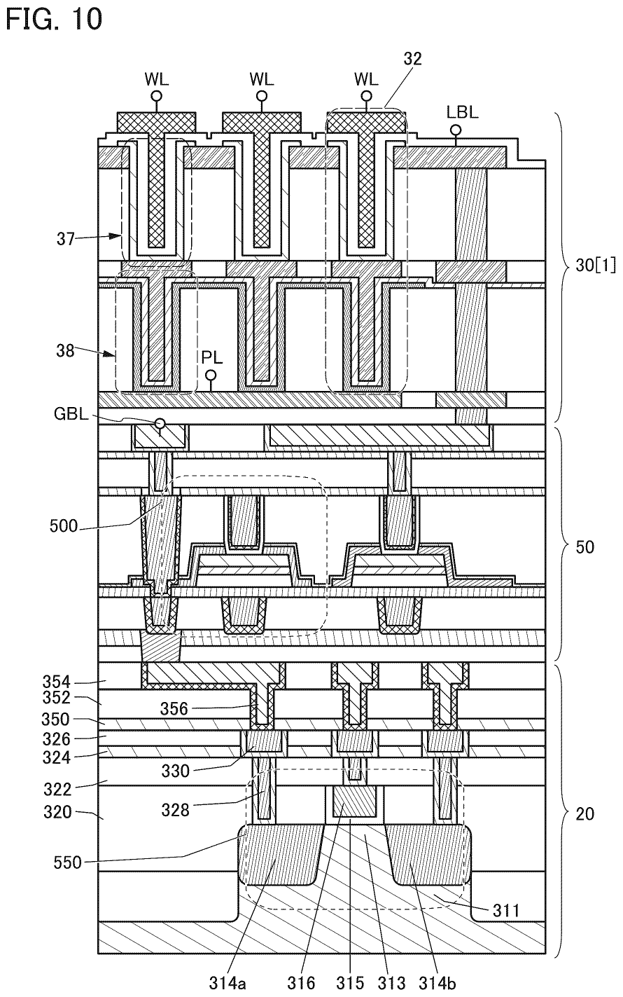

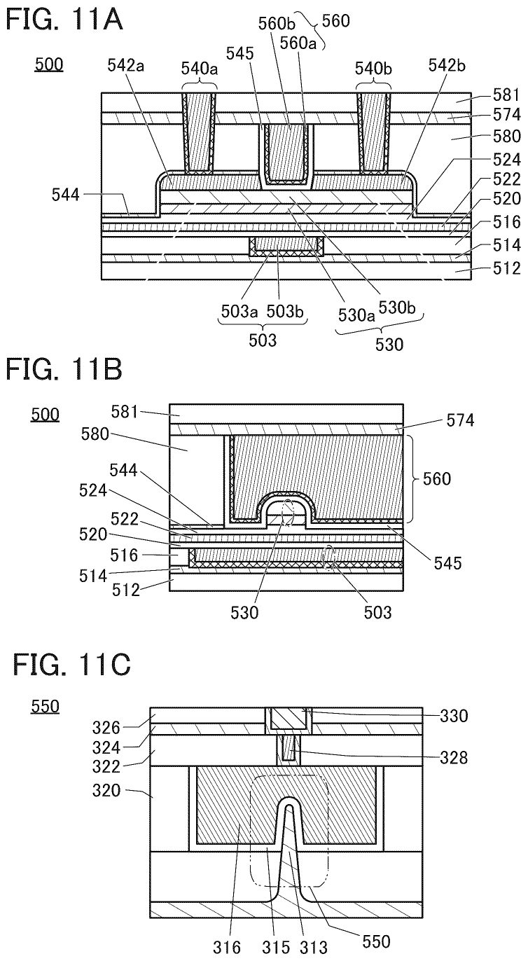

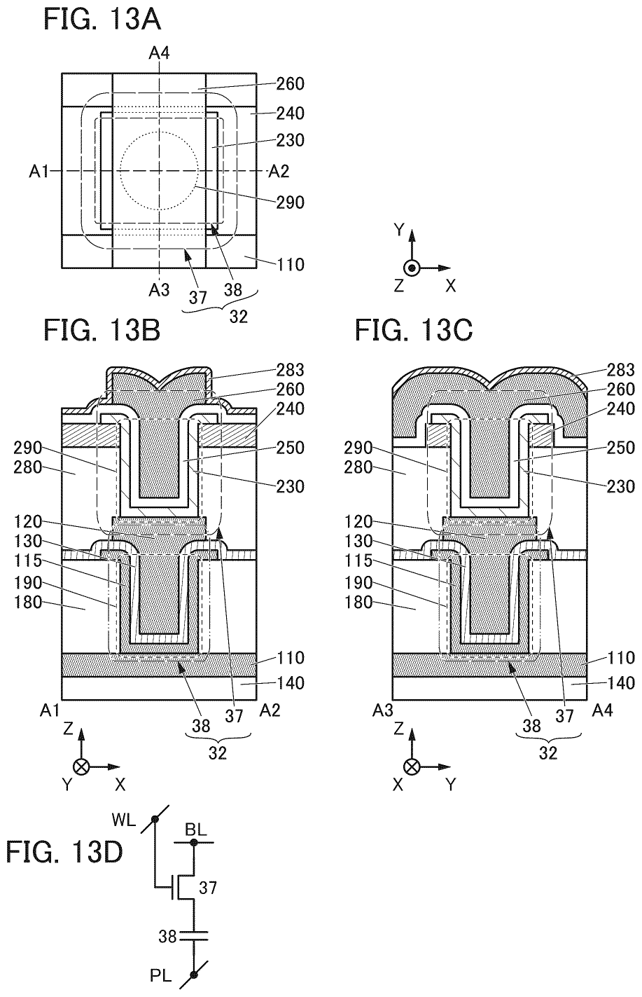

FIG. 10 illustrates part of a cross-sectional structure of a semiconductor device. The semiconductor device illustrated in FIG. 10 includes a transistor 550, transistors 500, the transistors 37, and the capacitors 38. The transistor 37 and the capacitor 38 are components of the above-described memory cell 32. FIG. 11A is a cross-sectional view of the transistor 500 in the channel length direction, FIG. 11B is a cross-sectional view of the transistor 500 in the channel width direction, and FIG. 11C is a cross-sectional view of the transistor 550 in the channel width direction. FIG. 13A is a top view of the transistor 37 and the capacitor 38, FIG. 13B and FIG. 13C are cross-sectional views of the transistor 37 and the capacitor 38, and FIG. 13D is a circuit diagram of the transistor 37 and the capacitor 38.

In FIG. 10, the transistor 550 corresponds to the Si transistor included in the element layer 20, the transistor 500 corresponds to the OS transistor included in the element layer 50, and the transistor 37 and the capacitor 38 correspond to the OS transistor and the capacitor included in the element layer 30[1], respectively.

In FIG. 10, the transistor 500 is provided above the transistor 550, and the transistor 37 and the capacitor 38 are provided above the transistor 550 and the transistor 500.

Note that in FIG. 10, the reference numerals WL, LBL, PL, GBL, and the like correspond to the reference numerals applied to the wirings in FIG. 3B and the like. A constant potential is supplied to the wiring PL, and a signal for driving the word line is supplied to the wiring WL. When the wiring WL supplied with the signal for driving the word line is positioned in the upper layer of the wiring PL supplied with the constant potential, the influence of noise on the element layer 50 in the lower layer of the element layer 30[1] can be reduced. When the capacitor 38 is positioned in the upper layer of the wiring PL supplied with a constant potential, the influence of noise on the element layer 30[1] due to driving of the amplifier circuit 51 included in the element layer 50 can be reduced.

The wiring LBL is provided to connect the transistor 37 included in the element layer 30[1] and the transistor 500 included in the element layer 50 (corresponding to the transistor 52 in FIG. 6C) through a conductor provided between the element layer 30[1] and the element layer 50. The wiring GBL is provided to connect the transistor 500 included in the element layer 50 (corresponding to the transistor 55 in FIG. 6C) and the transistor 550 included in the element layer 20 (corresponding to the transistor 85_3 and the like in FIG. 7A) through a conductor provided between the element layer 50 and the element layer 20.

### Transistor 550

The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 11C, the top surface and a side surface in the channel width direction of the semiconductor region 313 of the transistor 550 are covered with the conductor 316 with the insulator 315 therebetween. Such a Fin-type transistor 550 can have an increased effective channel width and thus have improved on-state characteristics. In addition, contribution of the electric field of a gate electrode can be increased, so that the off-state characteristics of the transistor 550 can be improved.

Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably include a semiconductor such as a silicon-based semiconductor, and preferably include single crystal silicon. Alternatively, the regions may be formed using a material containing Ge (germanium), SiGe (silicon germanium), GaAs (gallium arsenide), GaAlAs (gallium aluminum arsenide), or the like. A structure using silicon whose effective mass is controlled by applying stress to a crystal lattice and changing lattice spacing may be employed. Alternatively, the transistor 550 may be a HEMT (High Electron Mobility Transistor) using GaAs and GaAlAs, or the like.

The low-resistance region 314a and the low-resistance region 314b include an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, it is possible to use a semiconductor material such as silicon containing the element that imparts n-type conductivity, such as arsenic or phosphorus, or the element that imparts p-type conductivity, such as boron, or a conductive material such as a metal material, an alloy material, or a metal oxide material.

Note that since a work function depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (silicon on Insulator) substrate or the like.

As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature annealing, and an SOI substrate formed by a Smart-Cut method in which a semiconductor substrate is cleaved by utilizing growth of a minute void, which is formed by implantation of a hydrogen ion, by heat treatment; an ELTRAN method (registered trademark: Epitaxial Layer Transfer); or the like. A transistor formed using a single crystal substrate includes a single crystal semiconductor in a channel formation region.

An insulator 320, an insulator 322, an insulator 324, and an insulator 326 are sequentially stacked to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, the top surface of the insulator 322 may be planarized by planarization treatment using a chemical mechanical polishing (CMP) method or the like to have improved planarity.

For the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. The film that inhibits hydrogen diffusion is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm², preferably less than or equal to 5×10¹⁵ atoms/cm², in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for the interlayer film, parasitic capacitance generated between wirings can be reduced.

A conductor 328 that is connected to the transistor 500, a conductor 330, and the like are embedded in the insulator 320, the insulator 322, the insulator 324, and the insulator 326. Note that the conductor 328 and the conductor 330 each have a function of a plug or a wiring. A plurality of conductors having a function of a plugs or a wiring are collectively denoted by the same reference numeral in some cases. In this specification and the like, a wiring and a plug connected to the wiring may be a single component. That is, part of a conductor functions as a wiring in some cases and part of the conductor functions as a plug in other cases.

As a material for each of the plugs and wirings (the conductor 328, the conductor 330, and the like), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, an insulator 350, an insulator 352, and an insulator 354 are stacked sequentially in FIG. 10. Furthermore, a conductor 356 is formed in the insulator 350, the insulator 352, and the insulator 354. The conductor 356 has a function of a plug or a wiring that is connected to the transistor 550. Note that the conductor 356 can be formed using a material similar to that for the conductor 328 and the conductor 330.

Note that for example, the insulator 350 is preferably formed using an insulator having a barrier property against hydrogen, like the insulator 324. Furthermore, the conductor 356 preferably includes a conductor having a barrier property against hydrogen. The conductor having a barrier property against hydrogen is formed particularly in an opening portion of the insulator 350 having a barrier property against hydrogen. With this structure, the transistor 550 and the transistor 500 can be separated with a barrier layer, so that hydrogen diffusion from the transistor 550 into the transistor 500 can be inhibited.

Note that for the conductor having a barrier property against hydrogen, tantalum nitride or the like is preferably used, for example. By stacking tantalum nitride and tungsten, which has high conductivity, diffusion of hydrogen from the transistor 550 can be inhibited while the conductivity as a wiring is ensured. In that case, a tantalum nitride layer having a barrier property against hydrogen is preferably in contact with the insulator 350 having a barrier property against hydrogen.

In the above, the wiring layer including the conductor 356 is described; however, the semiconductor device of this embodiment is not limited thereto. A wiring layer similar to the wiring layer including the conductor 356 may have a single-layer structure or a stacked-layer structure of two or more layers.

### Transistor 500

Next, a structure of a transistor that can be used as the transistor 500 provided over the insulator 354 is described with reference to the transistor 500 illustrated in FIG. 11A and FIG. 11B.

Over the insulator 354 illustrated in FIG. 10, an insulator 512, an insulator 514, and an insulator 516 illustrated in FIG. 11A are stacked sequentially. A substance having a barrier property against oxygen, hydrogen, or the like is preferably used for any of the insulator 512, the insulator 514, and the insulator 516.

For example, for the insulator 514, it is preferable to use a film having a barrier property that prevents diffusion of hydrogen, impurities, or the like from the substrate 311, a region where the transistor 550 is provided, or the like into a region where the transistor 500 is provided. Thus, a material similar to that for the insulator 324 can be used.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. The film that inhibits hydrogen diffusion is specifically a film from which a small amount of hydrogen is released.

As the film having a barrier property against hydrogen, a metal oxide such as aluminum oxide, hafnium oxide, or tantalum oxide is preferably used for the insulator 514, for example.

In particular, aluminum oxide has an excellent blocking effect that prevents passage of both oxygen and impurities such as hydrogen and moisture that cause a change in electrical characteristics of the transistor. Accordingly, the use of aluminum oxide can prevent entry of impurities such as hydrogen and moisture into the transistor 500 during and after a formation process of the transistor. In addition, release of oxygen from the oxide included in the transistor 500 can be inhibited. Thus, aluminum oxide is suitably used for a protective film of the transistor 500.

The insulator 512 and the insulator 516 can be formed using a material similar to that for the insulator 320, for example. In the case where a material with relatively low permittivity is used for these insulators, the parasitic capacitance between wirings can be reduced. A silicon oxide film, a silicon oxynitride film, or the like can be used for the insulator 512 and the insulator 516, for example.

As illustrated in FIG. 11A and FIG. 11B, the transistor 500 includes a conductor 503 positioned to be embedded in the insulator 514 and the insulator 516, an insulator 520 positioned over the insulator 516 and the conductor 503, an insulator 522 positioned over the insulator 520, an insulator 524 positioned over the insulator 522, an oxide 530a positioned over the insulator 524, an oxide 530b positioned over the oxide 530a, a conductor 542a and a conductor 542b positioned apart from each other over the oxide 530b, an insulator 580 that is positioned over the conductor 542a and the conductor 542b and has an opening overlapping with an area between the conductor 542a and the conductor 542b, an insulator 545 positioned on the bottom surface and a side surface of the opening, and a conductor 560 that is positioned on a formation surface of the insulator 545.

As illustrated in FIG. 11A and FIG. 11B, an insulator 544 is preferably positioned between the insulator 580 and the oxide 530a, the oxide 530b, the conductor 542a, and the conductor 542b. In addition, as illustrated in FIG. 11A and FIG. 11B, the conductor 560 preferably includes a conductor 560a provided inside the insulator 545 and a conductor 560b provided to be embedded inside the conductor 560a. Moreover, as illustrated in FIG. 11A and FIG. 11B, an insulator 574 is preferably positioned over the insulator 580, the conductor 560, and the insulator 545.

Note that in this specification and the like, the oxide 530a and the oxide 530b are collectively referred to as an oxide 530 in some cases.

Note that the transistor 500 is illustrated to have a structure in which two layers, the oxide 530a and the oxide 530b, are stacked in the region where the channel is formed and its vicinity; however, the present invention is not limited thereto. For example, a single layer of the oxide 530b or a stacked-layer structure of three or more layers may be provided.

Although the conductor 560 has a two-layer structure in the transistor 500, the present invention is not limited thereto. For example, the conductor 560 may have a single-layer structure or a stacked-layer structure of three or more layers. The transistor 500 illustrated in FIG. 10 and FIG. 11A is just an example and is not limited to the structure illustrated therein, and an appropriate transistor can be used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Therefore, the conductor 560 can be formed without an alignment margin, resulting in a reduction in the area occupied by the transistor 500. Accordingly, miniaturization and high integration of the semiconductor device can be achieved.

Note that FIG. 10 illustrates the case where the conductor 542a and the conductor 542b extend beyond the end portion of the metal oxide 530 (the metal oxide 530a and the metal oxide 530b); however, the structure is not limited thereto, and the end portions of the conductor 542a and the conductor 542b and the end portion of the metal oxide 530 may be aligned with each other as illustrated in FIG. 11A.

Since the conductor 560 is formed in the region between the conductor 542a and the conductor 542b in a self-aligned manner, the conductor 560 does not have a region overlapping with the conductor 542a or the conductor 542b. Thus, parasitic capacitance between the conductor 560 and each of the conductor 542a and the conductor 542b can be reduced. As a result, the transistor 500 can have increased switching speed and excellent frequency characteristics.

The conductor 560 sometimes functions as a first gate (also referred to as top gate) electrode. The conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, a drain current at the time when a potential applied to the conductor 560 is 0 V can be made lower in the case where a negative potential is applied to the conductor 503 than in the case where a negative potential is not applied to the conductor 503.

The conductor 503 is positioned to overlap with the oxide 530 and the conductor 560. Accordingly, when a potential is applied to the conductor 560 and the conductor 503, an electric field generated from the conductor 560 and an electric field generated from the conductor 503 are connected, thereby covering the channel formation region in the oxide 530.

In this specification and the like, a transistor structure where a channel formation region is electrically surrounded by an electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can also be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor has the S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. In the transistor having any of the S-channel structure, GAA structure, and LGAA structure, the channel formation region that is formed at the interface between the oxide 530 and the gate insulator or in the vicinity of the interface can spread throughout the entire bulk of the oxide 530. Accordingly, the density of current flowing through the transistor can be increased, which can be expected to increase the on-state current of the transistor or increase the field-effect mobility of the transistor.

The conductor 503 has a structure similar to that of the conductor 518; a conductor 503a is formed in contact with an inner wall of an opening in the insulator 514 and the insulator 516, and a conductor 503b is formed over the conductor 503a to be embedded in the opening. Although the conductor 503a and the conductor 503b are stacked in the transistor 500, the present invention is not limited thereto. For example, the conductor 503 may have a single-layer structure or a stacked-layer structure of three or more layers.

Here, for the conductor 503a, it is preferable to use a conductive material having a function of inhibiting diffusion of impurities such as a hydrogen atom, a hydrogen molecule, a water molecule, and a copper atom (a conductive material through which the impurities are less likely to pass). Alternatively, it is preferable to use a conductive material having a function of inhibiting diffusion of oxygen (e.g., at least one of an oxygen atom, an oxygen molecule, and the like) (a conductive material through which the above oxygen is less likely to pass). Note that in this specification, the function of inhibiting diffusion of impurities or oxygen means a function of inhibiting diffusion of any one or all of the above impurities and the above oxygen.

For example, when the conductor 503a has a function of inhibiting diffusion of oxygen, a reduction in conductivity of the conductor 503b due to oxidation can be inhibited.

In the case where the conductor 503 also functions as a wiring, the conductor 503b is preferably formed using a conductive material with high conductivity that includes tungsten, copper, or aluminum as its main component. Although the conductor 503 is illustrated to have a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator including oxygen more than that in the stoichiometric composition is preferably used as the insulator 524 in contact with the oxide 530. Such oxygen is easily released from the film by heating. In this specification and the like, oxygen released by heating is sometimes referred to as excess oxygen. That is, a region including excess oxygen (also referred to as an “excess-oxygen region”) is preferably formed in the insulator 524. When such an insulator including excess oxygen is provided in contact with the oxide 530, oxygen vacancies (Vo) in the oxide 530 can be reduced and the reliability of the transistor 500 can be increased. Note that when hydrogen enters the oxygen vacancies in the oxide 530, such defects (hereinafter referred to as VoH in some cases) serve as donors and generate electrons serving as carriers in some cases. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen. In one embodiment of the present invention, VoH in the oxide 530 is preferably reduced as much as possible so that the oxide 530 becomes a highly purified intrinsic or substantially highly purified intrinsic oxide. In order to obtain such an oxide semiconductor with sufficiently reduced VoH, it is important to remove impurities such as moisture and hydrogen in the oxide semiconductor (this treatment is also referred to as “dehydration” or “dehydrogenation treatment”) and supply oxygen to the oxide semiconductor to fill oxygen vacancies (this treatment is also referred to as “oxygen adding treatment”). When an oxide semiconductor with sufficiently reduced impurities such as VoH is used for a channel formation region of a transistor, the transistor can have stable electrical characteristics.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

Any one or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when reaction in which a bond of VoH is cut occurs, i.e., reaction of “VoH→Vo+H” occurs. Part of hydrogen generated at this time is bonded to oxygen and is removed as H₂O from the oxide 530 or an insulator in the vicinity of the oxide 530 in some cases. Part of hydrogen is gettered into the conductors 542a and 542b in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The microwave treatment is performed under a pressure of 133 Pa or higher, preferably 200 Pa or higher, further preferably 400 Pa or higher. As a gas introduced into an apparatus for performing the microwave treatment, for example, oxygen and argon are used and the oxygen flow rate ratio (O₂/(O₂+Ar)) is lower than or equal to 50 %, preferably higher than or equal to 10 % and lower than or equal to 30 %.

In the formation process of the transistor 500, the heat treatment is preferably performed with the surface of the oxide 530 exposed. For example, the heat treatment is performed at a temperature higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at higher than or equal to 10 ppm, higher than or equal to 1 %, or higher than or equal to 10 %. For example, the heat treatment is preferably performed in an oxygen atmosphere. Accordingly, oxygen can be supplied to the oxide 530 to reduce oxygen vacancies (Vo). Alternatively, the heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at higher than or equal to 10 ppm, higher than or equal to 1 %, or higher than or equal to 10 % in order to compensate for released oxygen. Alternatively, the heat treatment may be performed in such a manner that heat treatment is performed in an atmosphere containing an oxidizing gas at higher than or equal to 10 ppm, higher than or equal to 1 %, or higher than or equal to 10 %, and then another heat treatment is successively performed in a nitrogen gas or inert gas atmosphere.

Note that oxygen adding treatment performed on the oxide 530 can promote reaction in which oxygen vacancies in the oxide 530 are filled with supplied oxygen, i.e., reaction of “Vo+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In the case where the insulator 524 includes an excess-oxygen region, the insulator 522 preferably has a function of inhibiting diffusion of oxygen (e.g., oxygen atoms and oxygen molecules) (the insulator 522 through which the above oxide is less likely to pass).

The insulator 522 preferably has a function of inhibiting diffusion of oxygen, impurities, or the like, in which case diffusion of oxygen included in the oxide 530 to the insulator 520 side is prevented. Furthermore, the conductor 503 can be inhibited from reacting with oxygen included in the insulator 524, the oxide 530, or the like.

The insulator 522 preferably has a single-layer structure or a stacked-layer structure using an insulator including what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba, Sr)TiO3 (BST), for example. As miniaturization and high integration of transistors progress, a problem such as off-state current might arise because of a thinner gate insulating film. When a high-k material is used for an insulator functioning as the gate insulating film, a gate potential during transistor operation can be reduced while the physical thickness is maintained.

It is particularly preferable to use an insulator including an oxide of one or both of aluminum and hafnium, which is an insulating material having a function of inhibiting diffusion of impurities, oxygen, and the like (an insulating material through which the above oxygen is less likely to pass). Aluminum oxide, hafnium oxide, an oxide including aluminum and hafnium (hafnium aluminate), or the like is preferably used for the insulator including an oxide of one or both of aluminum and hafnium. The insulator 522 formed of such a material functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to the insulator, for example. Alternatively, the insulator may be subjected to nitriding treatment. Silicon oxide, silicon oxynitride, or silicon nitride may be stacked over the insulator.

It is preferable that the insulator 520 be thermally stable. For example, silicon oxide and silicon oxynitride are preferred because of their thermal stability. Furthermore, a combination of an insulator that is a high-k material and silicon oxide or silicon oxynitride enables the insulator 520 to have a stacked-layer structure that has thermal stability and high relative permittivity.

Note that the transistor 500 in FIG. 11A and FIG. 11B includes the insulator 520, the insulator 522, and the insulator 524 as the second gate insulating film having a three-layer structure; however, the second gate insulating film may have a single-layer structure, a two-layer structure, or a stacked-layer structure of four or more layers. In such a case, the stacked layers are not necessarily formed of the same material and may be formed of different materials.

In the transistor 500, a metal oxide functioning as an oxide semiconductor is used as the oxide 530 including the channel formation region.

The metal oxide functioning as an oxide semiconductor may be formed by a sputtering method or an ALD (Atomic Layer Deposition) method. Note that the metal oxide functioning as an oxide semiconductor will be described in detail in another embodiment.

The metal oxide functioning as the channel formation region in the oxide 530 has a band gap of preferably 2 eV or more, further preferably 2.5 eV or more. The use of a metal oxide having such a wide band gap can reduce the off-state current of the transistor.

When the oxide 530 includes the oxide 530a under the oxide 530b, it is possible to inhibit diffusion of impurities into the oxide 530b from the components formed below the oxide 530a.

Note that the oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a bonding portion of the oxide 530a and the oxide 530b. In other words, the energy level of the conduction band minimum at the bonding portion of the oxide 530a and the oxide 530b continuously changes or is continuously connected. To change the energy level gradually, the density of defect states in a mixed layer formed at the interface between the oxide 530a and the oxide 530b is preferably made low.

Specifically, when the oxide 530a and the oxide 530b include a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is preferably used for the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including any of the above metal elements as its component; an alloy including a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

Although the conductor 542a and the conductor 542b have a single-layer structure in FIG. 11A, they may have a stacked-layer structure of two or more layers. For example, it is preferable to stack a tantalum nitride film and a tungsten film. Alternatively, a titanium film and an aluminum film may be stacked. Other examples include a two-layer structure where an aluminum film is stacked over a tungsten film, a two-layer structure where a copper film is stacked over a copper-magnesium-aluminum alloy film, a two-layer structure where a copper film is stacked over a titanium film, and a two-layer structure where a copper film is stacked over a tungsten film.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material including indium oxide, tin oxide, or zinc oxide may be used.

The insulator 544 is provided to cover the conductor 542a and the conductor 542b and inhibits oxidation of the conductor 542a and the conductor 542b. Here, the insulator 544 may be provided to cover a side surface of the oxide 530 and to be in contact with the insulator 524.

A metal oxide including one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use, as the insulator 544, an insulator including an oxide of one or both of aluminum and hafnium, such as aluminum oxide, hafnium oxide, or an oxide including aluminum and hafnium (hafnium aluminate). In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

The insulator 544 can inhibit impurities such as water and hydrogen included in the insulator 580 from diffusing into the oxide 530b. Moreover, the oxidation of the conductors 542a and 542b due to excess oxygen included in the insulator 580 can be inhibited.

The insulator 545 functions as a first gate insulating film. Like the insulator 524, the insulator 545 is preferably formed using an insulator that includes excess oxygen and releases oxygen by heating.

Specifically, it is possible to use any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide each including excess oxygen. In particular, silicon oxide and silicon oxynitride, which have thermal stability, are preferable.

When an insulator including excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen included in the insulator 545 to the oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as off-state current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have high relative permittivity.

Although the conductor 560 that functions as the first gate electrode and has a two-layer structure is shown in FIG. 11A and FIG. 11B, a single-layer structure or a stacked-layer structure of three or more layers may be employed.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, a reduction in the conductivity of the conductor 560b because of oxidation due to oxygen included in the insulator 545 can be inhibited. As a conductive material having a function of inhibiting diffusion of oxygen, for example, tantalum, tantalum nitride, ruthenium, ruthenium oxide, or the like is preferably used. Alternatively, the conductor 560a can be formed using an oxide semiconductor that can be used for the oxide 530. In that case, when the conductor 560b is formed by a sputtering method, the conductor 560a can have a reduced electrical resistance and become a conductor. Such a conductor can be referred to as an OC (Oxide Conductor) electrode.

The conductor 560b is preferably formed using a conductive material including tungsten, copper, or aluminum as its main component. The conductor 560b also functions as a wiring and thus is preferably formed using a conductor having high conductivity. For example, a conductive material including tungsten, copper, or aluminum as its main component can be used. The conductor 560b may have a stacked-layer structure, for example, a stacked-layer structure of titanium or titanium nitride and the above conductive material.

The insulator 580 is provided over the conductor 542a and the conductor 542b with the insulator 544 therebetween. The insulator 580 preferably includes an excess-oxygen region. For example, the insulator 580 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride, which have thermal stability, are preferable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with the top surface of the insulator 580, the top surface of the conductor 560, and the top surface of the insulator 545. When the insulator 574 is formed by a sputtering method, excess-oxygen regions can be provided in the insulator 545 and the insulator 580. Accordingly, oxygen can be supplied from the excess-oxygen regions to the oxide 530.

For example, a metal oxide including one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also function as a barrier film against impurities such as hydrogen.

An insulator 581 functioning as an interlayer film is preferably provided over the insulator 574. As in the insulator 524 or the like, the concentration of impurities such as water or hydrogen in the insulator 581 is preferably reduced.

A conductor 540a and a conductor 540b are positioned in openings formed in the insulator 581, the insulator 574, the insulator 580, and the insulator 544. The conductor 540a and the conductor 540b are provided to face each other with the conductor 560 therebetween.

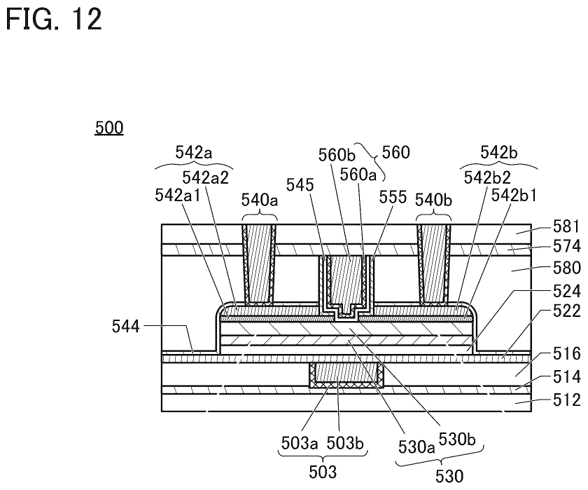

Note that the transistor that can be used in the present invention is not limited to the transistor 500 illustrated in FIG. 11A and FIG. 11B. For example, the transistor 500 having a structure illustrated in FIG. 12 may be used. The transistor 500 illustrated in FIG. 12 is different from the transistor illustrated in FIG. 11A and FIG. 11B in that an insulator 555 is used and that the conductor 542a (a conductor 542a1 and a conductor 542a2) and the conductor 542b (a conductor 542b1 and a conductor 542b2) each have a stacked-layer structure.

The conductor 542a has a stacked-layer structure of the conductor 542a1 and the conductor 542a2 over the conductor 542a1, and the conductor 542b has a stacked-layer structure of the conductor 542b1 and the conductor 542b2 over the conductor 542b1. The conductor 542a1 and the conductor 542b1 in contact with the oxide 530b are preferably conductors that are less likely to be oxidized, such as a metal nitride. Thus, excessive oxidation of the conductor 542a and the conductor 542b due to oxygen included in the oxide 530b can be prevented. Moreover, the conductor 542a2 and the conductor 542b2 are preferably conductors having higher conductivity than the conductor 542a1 and the conductor 542b1, such as a metal layer. Thus, the conductor 542a and the conductor 542b can function as wirings or electrodes having high conductivity. In this manner, it is possible to provide a semiconductor device in which the conductor 542a and the conductor 542b that function as wirings or electrodes are provided in contact with the top surface of the oxide 530 functioning as an active layer.

As the conductors 542a1 and 542b1, a metal nitride is preferably used; for example, a nitride including tantalum, a nitride including titanium, a nitride including molybdenum, a nitride including tungsten, a nitride including tantalum and aluminum, or a nitride including titanium and aluminum is preferably used. In one embodiment of the present invention, a nitride containing tantalum is particularly preferable. As another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

The conductor 542a2 and the conductor 542b2 preferably have higher conductivity than the conductor 542a1 and the conductor 542b1. For example, the thicknesses of the conductor 542a2 and the conductor 542b2 are preferably larger than the thicknesses of the conductor 542a1 and the conductor 542b1. For the conductor 542a2 and the conductor 542b2, a conductor that can be used for the conductor 560b can be used. The above structure can reduce the resistance of the conductor 542a2 and the conductor 542b2.

For example, tantalum nitride or titanium nitride can be used for the conductor 542a1 and the conductor 542b1, and tungsten can be used for the conductor 542a2 and the conductor 542b2.

As illustrated in FIG. 12, in a cross-sectional view of the transistor 500 in the channel length direction, the distance between the conductor 542a1 and the conductor 542b1 is smaller than the distance between the conductor 542a2 and the conductor 542b2. With such a structure, the distance between the source and the drain can be shortened, and the channel length can be accordingly shortened. Thus, the frequency characteristics of the transistor 500 can be improved. In this manner, miniaturization of the semiconductor device enables the semiconductor device to have a higher operating speed.

The insulator 555 is preferably an insulator that is less likely to be oxidized, such as a nitride. The insulator 555 is formed in contact with a side surface of the conductor 542a2 and a side surface of the conductor 542b2 and has a function of protecting the conductor 542a2 and the conductor 542b2. The insulator 555 is exposed to an oxidized atmosphere, and thus is preferably an inorganic insulator that is less likely to be oxidized. Since the insulator 555 is in contact with the conductor 542a2 and the conductor 542b2, the insulator 555 is preferably an inorganic insulator that is less likely to oxidize the conductors 542a2 and 542b2. Therefore, for the insulator 555, an insulating material having a barrier property against oxygen is preferably used. For example, silicon nitride can be used for the insulator 555.

The transistor 500 illustrated in FIG. 12 is formed in the following manner: an opening is formed in the insulator 580 and the insulator 544, the insulator 555 is formed in contact with the sidewall of the opening, and then the conductor 542a1 and the conductor 542b1 are separated using a mask. Here, the opening overlaps with a region between the conductor 542a2 and the conductor 542b2. The conductor 542a1 and the conductor 542b1 are formed to partly extend in the opening. Thus, in the opening, the insulator 555 is in contact with the top surface of the conductors 542a1, the top surface of the conductor 542b1, the side surface of the conductor 542a2, and the side surface of the conductor 542b2. The insulator 545 is in contact with the top surface of the oxide 530 in a region between the conductor 542a1 and the conductor 542b1.

Heat treatment in an atmosphere containing oxygen is preferably performed after the separation of the conductor into the conductor 542a1 and the conductor 542b1 and before the formation of the insulator 545. Thus, oxygen can be supplied to the oxide 530a and the oxide 530b to reduce oxygen vacancies. Furthermore, since the insulator 555 is formed in contact with the side surface of the conductor 542a2 and the side surface of the conductor 542b2, excessive oxidation of the conductor 542a2 and the conductor 542b2 can be prevented. Accordingly, the transistor can have favorable electrical characteristics and higher reliability. In addition, variations in electrical characteristics of transistors formed over the same substrate can be reduced.

In the transistor 500, the insulator 524 may be formed into an island shape, as illustrated in FIG. 12. Here, the insulator 524 may be formed such that the side end portion thereof is substantially aligned with the side end portion of the oxide 530.

In the transistor 500, the insulator 522 may be in contact with the insulator 516 and the conductor 503, as illustrated in FIG. 12. In other words, a structure where the insulator 520 illustrated in FIG. 11A and FIG. 11B is not provided may be employed.

### Transistor 37 and Capacitor 38

FIG. 13A to FIG. 13C are a plan view and cross-sectional views of the transistor 37 and the capacitor 38, which are included in the memory cell 32 and can be used as components included in the element layer 30[1] in FIG. 10. FIG. 13A is a plan view of the memory cell 32. FIG. 13B and FIG. 13C are cross-sectional views of the memory cell 32. Here, FIG. 13B is a cross-sectional view of a portion indicated by the dashed-dotted line A1-A2 in FIG. 13A. FIG. 13C is a cross-sectional view of a portion indicated by the dashed-dotted line A3-A4 in FIG. 13A. Note that for clarity of the drawing, some components are omitted in the plan view of FIG. 13A.

FIG. 13A to FIG. 13C illustrate an insulator 140, a conductor 110 over the insulator 140, the memory cell 32 over the conductor 110, an insulator 180 over the conductor 110, an insulator 280, and an insulator 283 over the memory cell 32. The insulator 140, the insulator 180, the insulator 280, and the insulator 283 each function as an interlayer film. The conductor 110 functions as a wiring.

The memory cell 32 includes the capacitor 38 over the conductor 110 and the transistor 37 over the capacitor 38.

The capacitor 38 includes a conductor 115 over the conductor 110, an insulator 130 over the conductor 115, and a conductor 120 over the insulator 130. The conductor 120 functions as one of a pair of electrodes (sometimes referred to as an upper electrode), the conductor 115 functions as the other of the pair of electrodes (sometimes referred to as a lower electrode), and the insulator 130 functions as a dielectric. That is, the capacitor 38 forms a MIM (Metal-Insulator-Metal) capacitor.

As illustrated in FIG. 13B and FIG. 13C, an opening portion 190 reaching the conductor 110 is provided in the insulator 180. At least part of the conductor 115 is positioned in the opening portion 190. Note that the conductor 115 includes a region in contact with the top surface of the conductor 110 in the opening portion 190, a region in contact with a side surface of the insulator 180 in the opening portion 190, and a region in contact with at least part of the top surface of the insulator 180. The insulator 130 is provided so that at least part of the insulator 130 is positioned in the opening portion 190. The conductor 120 is provided so that at least part of the conductor 120 is positioned in the opening portion 190. Note that the conductor 120 is preferably provided to fill the opening portion 190 as illustrated in FIG. 13B and FIG. 13C.

The capacitor 38 has a structure in which the upper electrode and the lower electrode face each other with the dielectric therebetween on a side surface as well as the bottom surface in the opening portion 190; thus, the capacitance per unit area can be increased. Thus, the deeper the opening portion 190 is, the larger the capacitance of the capacitor 38 can be. Increasing the capacitance per unit area of the capacitor 38 in this manner can stabilize the read operation of the memory cell arrays. This also enables further miniaturization or high integration of the memory cells.

Note that the sidewall of the opening portion 190 is preferably perpendicular to the top surface of the conductor 110. In this case, the opening portion 190 has a cylindrical shape. This structure enables miniaturization or high integration of the memory cells.

The conductor 115 and the insulator 130 are stacked along the sidewall of the opening portion 190 and the top surface of the conductor 110. The conductor 120 is provided over the insulator 130 to fill the opening portion 190. The capacitor 38 having such a structure corresponds to the above-described trench capacitor (deep-hole stacked capacitor).

The insulator 280 is provided over the capacitor 38. That is, the insulator 280 is positioned over the conductor 115, the insulator 130, and the conductor 120. In other words, the conductor 120 is positioned under the insulator 280.

The transistor 37 includes the conductor 120, a conductor 240 over the insulator 280, an oxide semiconductor 230, an insulator 250 over the oxide semiconductor 230, and a conductor 260 over the insulator 250. The oxide semiconductor 230 functions as a semiconductor layer, the conductor 260 functions as a gate electrode, the insulator 250 functions as a gate insulator, the conductor 120 functions as one of a source electrode and a drain electrode, and the conductor 240 functions as the other of the source electrode and the drain electrode.

As illustrated in FIG. 13B and FIG. 13C, an opening portion 290 reaching the conductor 120 is provided in the insulator 280 and the conductor 240. At least part of the oxide semiconductor 230 is positioned in the opening portion 290. Note that the oxide semiconductor 230 includes a region in contact with the top surface of the conductor 120 in the opening portion 290, a region in contact with a side surface of the conductor 240 in the opening portion 290, and a region in contact with at least part of the top surface of the conductor 240. The insulator 250 is provided so that at least part of the insulator 250 is positioned in the opening portion 290. The conductor 260 is provided so that at least part of the conductor 260 is positioned in the opening portion 290. Note that the conductor 260 is preferably provided to fill the opening portion 290 as illustrated in FIG. 13B and FIG. 13C.

The oxide semiconductor 230 includes a region in contact with the side surface of the conductor 240 in the opening portion 290 and a region in contact with part of the top surface of the conductor 240. When the oxide semiconductor 230 is in contact with not only the side surface of the conductor 240 but also the top surface of the conductor 240 in this manner, the area where the oxide semiconductor 230 and the conductor 240 are in contact with each other can be increased.

As illustrated in FIG. 13A to FIG. 13C, the transistor 37 is provided to overlap with the capacitor 38. The opening portion 290 where part of the components of the transistor 37 is provided includes a region overlapping with the opening portion 190 where part of the components of the capacitor 38 is provided. In particular, since the conductor 120 has a function of one of the source electrode and the drain electrode of the transistor 37 and a function of the upper electrode of the capacitor 38, the transistor 37 and the capacitor 38 partly share the structure. With such a structure, the transistor 37 and the capacitor 38 can be provided without a great increase in the occupied area in the plan view. Thus, the area occupied by the memory cells 32 can be reduced, so that the memory cells 32 can be arranged densely and the memory capacity can be increased.

FIG. 13D is a circuit diagram of the memory cell 32. Here, the wiring BL corresponds to the conductor 240, the wiring WL corresponds to the conductor 260, and the wiring PL corresponds to the conductor 110. As illustrated in FIG. 13A to FIG. 13C, it is preferable that the conductor 260 be provided to extend in the Y direction and the conductor 240 be provided to extend in the X direction. In this structure, the wiring BL and the wiring WL are provided to intersect with each other. Although the wiring PL (the conductor 110) is provided in a plane shape in FIG. 13A, the present invention is not limited thereto. For example, the wiring PL may be provided parallel to the wiring WL (the conductor 260) or the wiring BL (the conductor 240).

The capacitor 38 includes the conductor 115, the insulator 130, and the conductor 120. The conductor 110 is provided below the conductor 115. The conductor 115 includes a region in contact with the conductor 110.

The conductor 110 is provided over the insulator 140. The conductor 110 functions as the wiring PL and can be provided in a plane shape, for example. A single layer or stacked layers of a conductor can be used for the conductor 110. For example, a conductive material with high conductivity such as tungsten can be used for the conductor 110. With the use of a conductive material with high conductivity, the conductivity of the conductor 110 can be improved and the wiring PL can function sufficiently.

The conductor 115 is preferably formed using a single layer or stacked layers of a conductive material that is less likely to be oxidized, a conductive material having a function of inhibiting diffusion of oxygen, or the like. For example, titanium nitride, indium tin oxide to which silicon is added, or the like may be used. Alternatively, for example, a structure in which titanium nitride is stacked over tungsten may be used. Alternatively, for example, a structure in which tungsten is stacked over first titanium nitride and second titanium nitride is stacked over the tungsten may be used. Even when an oxide insulator is used as the insulator 130, such a structure can inhibit the conductor 110 from being oxidized by the insulator 130. In the case of using an oxide insulator as the insulator 180, such a structure can inhibit the conductor 110 from being oxidized by the insulator 180.

The insulator 130 is provided over the conductor 115. The insulator 130 is provided in contact with the top surface and a side surface of the conductor 115. That is, the insulator 130 preferably covers the side end portion of the conductor 110. This can prevent a short circuit between the conductor 115 and the conductor 120.

Alternatively, the side end portion of the insulator 130 and the side end portion of the conductor 115 may be aligned with each other. This structure enables the insulator 130 and the conductor 115 to be formed using the same mask, so that the formation process of the element layer 30[1] can be simplified.

For the insulator 130, a material with a high relative permittivity, what is called a high-k material, is preferably used. Using a high-k material for the insulator 130 allows the insulator 130 to be thick enough to inhibit a leakage current and the capacitor 38 to have a sufficiently high capacitance.

It is preferable to use stacked insulators formed of a high-k material for the insulator 130, and it is preferable to use a stacked-layer structure of a material with high relative permittivity (a high-k material) and a material having a higher dielectric strength than the high-k material. As the insulator 130, an insulating film in which zirconium oxide, aluminum oxide, and zirconium oxide are stacked in this order can be used, for example. Alternatively, an insulating film in which zirconium oxide, aluminum oxide, zirconium oxide, and aluminum oxide are stacked in this order can be used, for example. As another example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, can increase the dielectric strength and inhibit electrostatic breakdown of the capacitor 38.

Alternatively, a material that can have ferroelectricity may be used for the insulator 130. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of the number of hafnium atoms to the number of atoms of the element J1 can be set as appropriate; the atomic ratio of the number of hafnium atoms to the number of atoms of the element J1 is, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of a zirconium atom to the element J2 can be set as appropriate; the atomic ratio of a zirconium atom to the element J2 is, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO3 with a k-alumina-type structure, and the like.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 130 can have a stacked-layer structure of a plurality of materials selected from the above-listed materials. Note that the crystal structures (properties) of the above-listed materials and the like can be changed depending on the processes as well as the formation conditions; thus, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being processed into a thin film of several nanometers. Here, the thickness of the insulator 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness is preferably greater than or equal to 8 nm and less than or equal to 12 nm, for example. With the use of a ferroelectric layer that can have a small thickness, the capacitor 38 can be combined with a miniaturized semiconductor element such as a transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupied area) less than or equal to 100 μm², less than or equal to 10 μm², less than or equal to 1 μm², or less than or equal to 0.1 μm² in a top view. Furthermore, even with an area less than or equal to 10000 nm² or less than or equal to 1000 nm², a ferroelectric layer has ferroelectricity in some cases. With a small-area ferroelectric layer, the area occupied by the capacitor 38 can be reduced.

A ferroelectric is an insulator and has a property of causing internal polarization by application of an electric field from the outside and maintaining the polarization even after the electric field is made zero. Thus, with the use of a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 38, the memory cell described in this embodiment functions as a ferroelectric memory.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 130 can exhibit ferroelectricity, the insulator 130 needs to include a crystal. It is particularly preferable that the insulator 130 include a crystal having an orthorhombic crystal structure to exhibit ferroelectricity. Note that a crystal included in the insulator 130 may have one or more selected from cubic, tetragonal, orthorhombic, monoclinic, and hexagonal crystal structures. Alternatively, the insulator 130 may have an amorphous structure. In that case, the insulator 130 may have a composite structure including an amorphous structure and a crystal structure.

The conductor 120 is provided in contact with part of the top surface of the insulator 130. The side end portion of the conductor 120 is preferably positioned inward from the side end portion of the conductor 115 in both the X direction and the Y direction. Note that in the structure where the insulator 130 covers the side end portion of the conductor 115, the side end portion of the conductor 120 may be positioned outward from the side end portion of the conductor 115.

As the conductor 120, a single layer or stacked layers of any of the conductors described in the section [Conductor] below can be used. A conductive material that is less likely to be oxidized, a conductive material having a function of inhibiting diffusion of oxygen, or the like is preferably used for the conductor 120. For example, titanium nitride, tantalum nitride, or the like can be used. For example, a structure in which tantalum nitride is stacked over titanium nitride may be used. In that case, titanium nitride is in contact with the insulator 130 and tantalum nitride is in contact with the oxide semiconductor 230. Such a structure can inhibit the excessive oxidation of the conductor 120 due to the oxide semiconductor 230. In the case of using an oxide insulator for the insulator 130, the excessive oxidation of the conductor 120 due to the insulator 130 can be inhibited. Alternatively, for the conductor 120, a structure in which tungsten is stacked over titanium nitride may be used, for example.

The conductor 120 includes a region in contact with the oxide semiconductor 230 and thus is preferably formed using a conductive material containing oxygen described in the section [Conductor] below. When a conductive material containing oxygen is used for the conductor 120, the conductor 120 can maintain its conductivity even when absorbing oxygen. In addition, also in the case of using an insulator containing oxygen such as zirconium oxide as the insulator 130, the conductor 120 can maintain its conductivity, which is preferable. As the conductor 120, a single layer or stacked layers of indium tin oxide (also referred to as ITO), indium tin oxide to which silicon is added (also referred to as ITSO), indium zinc oxide (also refered to as IZO (registered trademark)), or the like can be used, for example.

The insulator 180, which functions as an interlayer film, preferably has a low relative permittivity. When a material with a low relative permittivity is used for an interlayer film, parasitic capacitance generated between wirings can be reduced. As the insulator 180, a single layer or stacked layers of an insulator containing a material with a low relative permittivity can be used. Silicon oxide and silicon oxynitride are preferable because they are thermally stable. Here, the insulator 180 contains at least silicon and oxygen.

As illustrated in FIG. 13A to FIG. 13C, the transistor 37 can have a structure including the conductor 120; the conductor 240 over the insulator 280; the oxide semiconductor 230 provided in contact with the top surface of the conductor 120, which is exposed in the opening portion 290, a side surface of the insulator 280 in the opening portion 290, the side surface of the conductor 240 in the opening portion 290, and at least part of the top surface of the conductor 240; the insulator 250 provided in contact with the top surface of the oxide semiconductor 230; and the conductor 260 provided in contact with the top surface of the insulator 250.

At least part of the components of the transistor 37 is positioned in the opening portion 290. Here, the bottom portion of the opening portion 290 is the top surface of the conductor 120, and the sidewall of the opening portion 290 is the side surface of the insulator 280 and the side surface of the conductor 240.

Note that the sidewall of the opening portion 290 is preferably perpendicular to the top surface of the conductor 110. At this time, the opening portion 290 has a cylindrical shape. This structure enables miniaturization or high integration of the memory cell.

Although this embodiment describes the example where the opening portion 290 has a circular shape in the plan view, the present invention is not limited thereto. For example, the opening portion 290 in the plan view may have an almost circular shape such as an elliptical shape, a polygonal shape such as a quadrangular shape, or a polygonal shape such as a quadrangular shape with rounded corners. In that case, the maximum width of the opening portion 290 is calculated as appropriate in accordance with the shape of the uppermost portion of the opening portion 290. For example, in the case where the opening portion is square in the plan view, the maximum width of the opening portion 290 is preferably the length of a diagonal line of the uppermost portion of the opening portion 290.

Portions of the oxide semiconductor 230, the insulator 250, and the conductor 260 that are positioned in the opening portion 290 reflect the shape of the opening portion 290. Therefore, the oxide semiconductor 230 is provided to cover the bottom portion and the sidewall of the opening portion 290, the insulator 250 is provided to cover the oxide semiconductor 230, and the conductor 260 is provided to be embedded in a depressed portion, which reflects the shape of the opening portion 290, of the insulator 250.

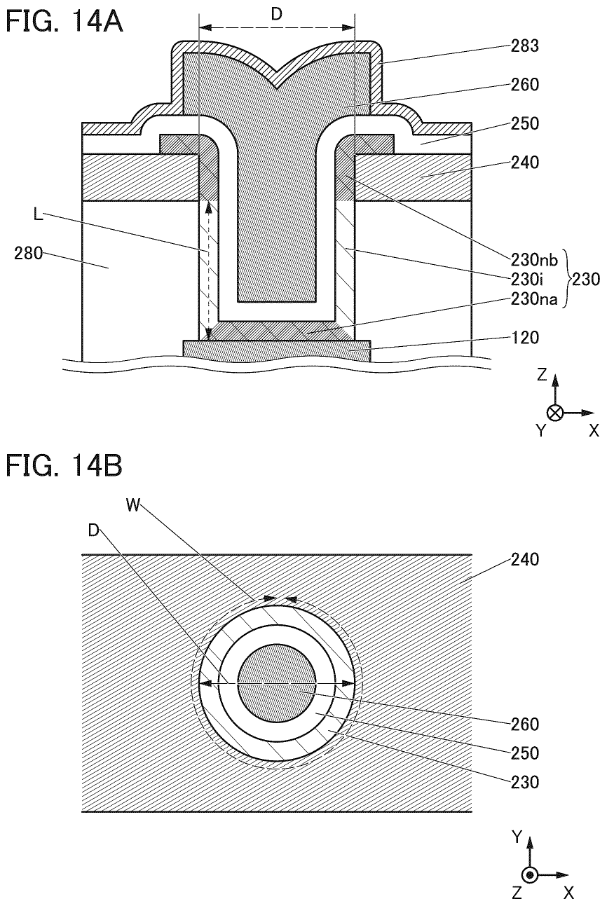

Here, FIG. 14A is an enlarged view of the oxide semiconductor 230 and the vicinity thereof in FIG. 13B. FIG. 14B is a cross-sectional view taken along the XY plane including the conductor 240.

As illustrated in FIG. 14A, the oxide semiconductor 230 includes a region 230i, and a region 230na and a region 230nb provided such that the region 230i is sandwiched therebetween.

The region 230na is a region of the oxide semiconductor 230 that is in contact with the conductor 120. At least part of the region 230na functions as one of a source region and a drain region of the transistor 37. The region 230nb is a region of the oxide semiconductor 230 that is in contact with the conductor 240. At least part of the region 230nb functions as the other of the source region and the drain region of the transistor 37. As illustrated in FIG. 14B, the conductor 240 is in contact with the entire outer circumference of the oxide semiconductor 230. Thus, the other of the source region and the drain region of the transistor 37 can be formed along the entire outer circumference of a portion of the oxide semiconductor 230 that is formed in the same layer as the conductor 240.

The region 230i is a region between the region 230na and the region 230nb in the oxide semiconductor 230. At least part of the region 230i functions as a channel formation region of the transistor 37. That is, the channel formation region of the transistor 37 is positioned in a region of the oxide semiconductor 230 between the conductor 120 and the conductor 240. It can also be said that the channel formation region of the transistor 37 is positioned in a region in contact with the insulator 280 or a region in the vicinity thereof in the oxide semiconductor 230.

The channel length of the transistor 37 is a distance between the source region and the drain region. In other words, the channel length of the transistor 37 is determined by the thickness of the insulator 280 over the conductor 120. In FIG. 14A, a channel length L of the transistor 37 is indicated by a dashed double-headed arrow. In the cross-sectional view, the channel length L is a distance between an end portion of the region where the oxide semiconductor 230 is in contact with the conductor 120 and an end portion of the region where the oxide semiconductor 230 is in contact with the conductor 240. That is, the channel length L corresponds to the length of the side surface of the insulator 280 on the opening portion 290 side in the cross-sectional view.

In a conventional transistor, the channel length is determined by the light exposure limit of photolithography. However, in the present invention, the channel length can be determined by the thickness of the insulator 280. Thus, the transistor 37 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm). Accordingly, the transistor 37 can have higher on-state current and improved frequency characteristics. Accordingly, the read speed and the write speed of the memory cells 32 can be increased, whereby a memory device with a high operation speed can be provided.

In addition, as described above, the channel formation region, the source region, and the drain region can be formed in the opening portion 290. Thus, the area occupied by the transistor 37 can be smaller than the area occupied by a conventional transistor in which a channel formation region, a source region, and a drain region are provided separately on the XY plane. This allows high integration of the memory device; therefore, the memory capacity per unit area can be increased.

Furthermore, in the XY plane including the channel formation region of the oxide semiconductor 230, as illustrated in FIG. 14B, the oxide semiconductor 230, the insulator 250, and the conductor 260 are provided concentrically. Therefore, a side surface of the conductor 260 provided at the center faces a side surface of the oxide semiconductor 230 with the insulator 250 therebetween. That is, in the plan view, the entire circumference of the oxide semiconductor 230 serves as the channel formation region. In this case, for example, the channel width of the transistor 37 is determined by the length of the outer circumference of the oxide semiconductor 230. In other words, it can be said that the channel width of the transistor 37 is determined by the maximum width of the opening portion 290 (the maximum diameter in the case where the opening portion 290 is circular in the plan view). In FIG. 14A and FIG. 14B, a maximum width D of the opening portion 290 is indicated by a dashed double-dotted double-headed arrow. In FIG. 14B, a channel width W of the transistor 37 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the film thicknesses of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be calculated to be “D×π”.

In the memory cell 32 of one embodiment of the present invention, the channel length L of the transistor 37 is preferably smaller than at least the channel width W of the transistor 37. The channel length L of the transistor 37 of one embodiment of the present invention is greater than or equal to 0.1 times and less than or equal to 0.99 times, preferably greater than or equal to 0.5 times and less than or equal to 0.8 times the channel width W of the transistor 37. This structure enables a transistor to have favorable electrical characteristics and high reliability.

In the case where the opening portion 290 is formed to be circular in the plan view, the oxide semiconductor 230, the insulator 250, and the conductor 260 are formed concentrically. This makes the distance between the conductor 260 and the oxide semiconductor 230 substantially uniform, so that a gate electric field can be substantially uniformly applied to the oxide semiconductor 230.

It is preferable that the channel formation region of the transistor using an oxide semiconductor in the semiconductor layer contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as VoH), which generates an electron serving as a carrier. Therefore, it is preferable that VoH be also decreased in the channel formation region. Thus, the channel formation region of the transistor is a high-resistance region having a low carrier concentration. Accordingly, the channel formation region of the transistor can be regarded as being i-type (intrinsic) or substantially i-type. Meanwhile, the source region and the drain region of the transistor using an oxide semiconductor in the semiconductor layer contain more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor are each an n-type region having a higher carrier concentration and a lower resistance than the channel formation region.

Although the opening portion 290 is provided so that the sidewall of the opening portion 290 is perpendicular to the top surface of the conductor 110 in FIG. 13B and FIG. 13C, the present invention is not limited thereto. The sidewall of the opening portion 290 may have a tapered shape, for example.

FIG. 13C illustrates a structure in which the side end portion of the oxide semiconductor 230 are positioned inward from the side end portion of the conductor 240. Note that the present invention is not limited thereto. For example, in the Y direction, the side end portion of the oxide semiconductor 230 and the side end portion of the conductor 240 may be aligned with each other. Alternatively, the side end portion of the oxide semiconductor 230 may be positioned outward from the side end portion of the conductor 240.

The metal oxide functioning as the oxide semiconductor 230 preferably has a band gap of 2 eV or higher, further preferably 2.5 eV or higher. With the use of a metal oxide having a wide band gap as the oxide semiconductor 230, the off-state current of the transistor can be reduced. By using a transistor with a low off-state current in a memory cell, stored data can be retained for a long time. In other words, refresh operation is not required or the frequency of refresh operation is extremely low, which leads to a sufficient reduction in power consumption of a memory cell array. The frequency of refresh operation in a general DRAM is approximately once per 60 msec, whereas the frequency of refresh operation in the semiconductor device of one embodiment of the present invention can be approximately once per 10 sec, which is 10 times or more or 100 times or more lower than the frequency of refresh operation in the general DRAM. In the semiconductor device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 230, a single layer or stacked layers of a metal oxide can be used.

As the oxide semiconductor 230, a metal oxide with a composition of In:M:Zn=1:3:2 [atomic ratio] or in the neighborhood thereof, a composition of In:M:Zn=1:3:4 [atomic ratio] or in the neighborhood thereof, a composition of In M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof may be specifically used. Note that a composition in the neighborhood includes the range of ±30 % of an intended atomic ratio. Gallium is preferably used as the element M.

A sputtering method or an atomic layer deposition (ALD) method can be suitably used for forming the metal oxide. Note that in the case where the metal oxide is formed by a sputtering method, the composition of the formed metal oxide may be different from the composition of a sputtering target. In particular, the content percentage of the zinc in the formed metal oxide may be reduced to approximately 50 % of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 230, the CAAC-OS or the nc-OS is preferably used, and the CAAC-OS is particularly preferably used.

CAAC-OS preferably includes a plurality of layered crystal regions and a c-axis is preferably aligned in a normal direction of a surface where the CAAC-OS is formed. For example, the oxide semiconductor 230 preferably includes a layered crystal that is substantially parallel to the sidewall of the opening portion 290, particularly the side surface of the insulator 280. With this structure, the layered crystals of the oxide semiconductor 230 are formed substantially in parallel with the channel length direction of the transistor 37, so that the on-state current of the transistor can be increased.

Although the oxide semiconductor 230 has a single layer in FIG. 13B and FIG. 13C, the present invention is not limited thereto. The oxide semiconductor 230 may have a stacked-layer structure of a plurality of oxide layers with different chemical compositions. For example, a structure in which a plurality of kinds of metal oxides selected from the above-described metal oxides are stacked as appropriate may be used.

### Another Modification Example

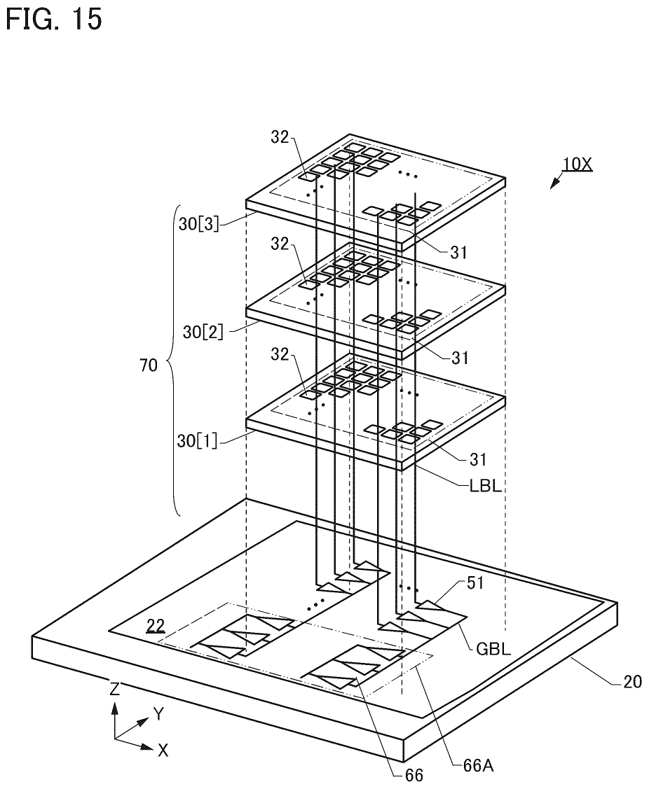

FIG. 15 illustrates a modification example of the above-described semiconductor device. A semiconductor device 10X illustrated in FIG. 15 is a structure example of a schematic perspective view in which the element layer 50 illustrated in FIG. 1B is omitted. The amplifier circuit 51 included in the element layer 50 is provided in the element layer 20. The amplifier circuit 51 provided in the element layer 20 is connected to the sense amplifier 66 through the wiring GBL provided in the element layer 20.

With the structure illustrated in FIG. 15, the area occupied by the peripheral circuit 22 in the element layer 20 is increased. However, the element layer 50 provided over the element layer 20 can be omitted, whereby manufacturing cost of the semiconductor device can be reduced.

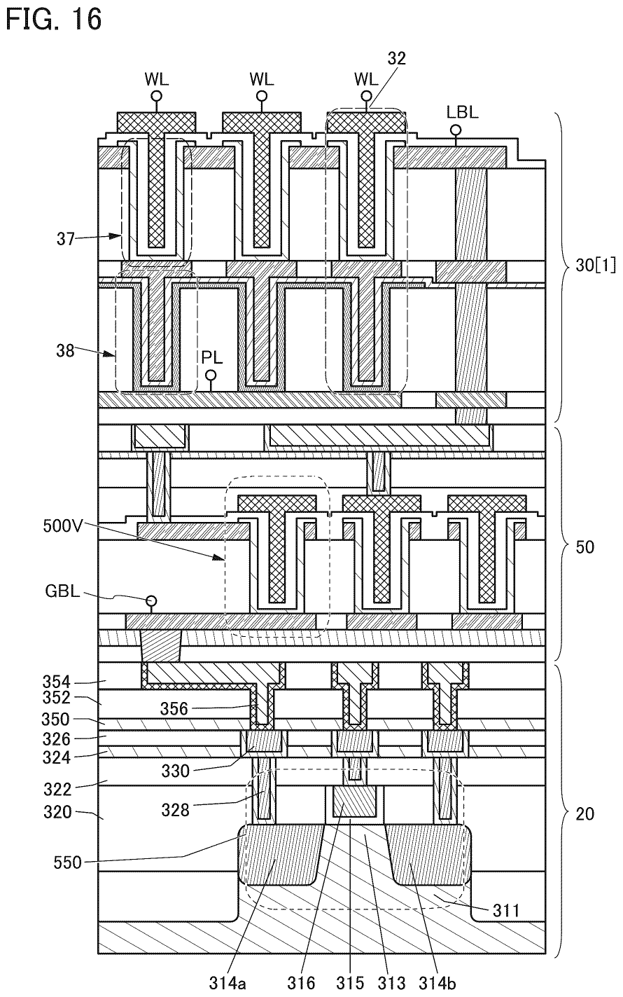

FIG. 16 illustrates a modification example of the above-described semiconductor device. A schematic cross-sectional view illustrated in FIG. 16 illustrates the structure of the transistor illustrated in FIG. 13A to FIG. 13C is used for the transistor 500 included in the element layer 50 in FIG. 10.

In FIG. 16, the reference numerals such as WL, LBL, PL, and GBL correspond to the reference numerals used for the wirings in FIG. 3B and the like. A constant potential is supplied to the wiring PL, and a signal for driving the word line is supplied to the wiring WL. When the wiring WL supplied with the signal for driving the word line is positioned above the wiring PL supplied with the constant potential, the influence of noise on the element layer 50 below the element layer 30[1] can be reduced. When the capacitor 38 is positioned in the upper layer of the wiring PL supplied with a constant potential, the influence of noise on the element layer 30[1] due to driving of the amplifier circuit 51 included in the element layer 50 can be reduced.

The wiring LBL is provided to connect the transistor 37 included in the element layer 30[1] and a transistor 500V (corresponding to the transistor 52 in FIG. 6C) included in the element layer 50 through a conductor provided between the element layer 30[1] and the element layer 50. The wiring GBL is provided to connect the transistor 500V (corresponding to the transistor 55 in FIG. 6C) included in the element layer 50 and the transistor 550 (corresponding to the transistor 85_3 in FIG. 7A and the like) included in the element layer 20 through a conductor provided between the element layer 50 and the element layer 20.

As illustrated in FIG. 14A and FIG. 14B, it is possible to increase the channel width per unit area and the on-state current of the transistor 500V used for the element layer 50 illustrated in FIG. 16. Thus, the amplifier circuit 51 including the transistor 500V can have increased operation speed.

At least part of the structure, method, and the like described in this embodiment can be implemented in appropriate combination with any of the other embodiments described in this specification.

### Embodiment 2

In this embodiment, a transistor including an oxide semiconductor in a channel formation region (OS transistor) is described. In the description of the OS transistor, comparison with a transistor including silicon in a channel formation region (also referred to as a Si transistor) is also described simply.

### OS Transistor

An oxide semiconductor having a low carrier concentration is preferably used for an OS transistor. For example, the carrier concentration in an oxide semiconductor in the channel formation region is lower than or equal to 1×1018 cm⁻³, preferably lower than 1×10¹⁷ cm⁻³, further preferably lower than 1×1016 cm⁻³, still further preferably lower than 1×10¹³ cm⁻³, yet further preferably lower than 1×1010 cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and thus has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that an impurity in an oxide semiconductor refers to, for example, elements other than the main components of the oxide semiconductor. For example, an element with a concentration lower than 0.1 atomic % can be regarded as an impurity.

An OS transistor is likely to have its electrical characteristics changed when impurities and oxygen vacancies exist in a channel formation region of the oxide semiconductor, which might affect the reliability. In some cases, a defect that is an oxygen vacancy into which hydrogen enters (hereinafter sometimes referred to as VoH) is formed in the oxide semiconductor of the OS transistor, which generates an electron serving as a carrier. Formation of VoH in the channel formation region may increase the donor concentration in the channel formation region. An increase in the donor concentration in the channel formation region may lead to a variation in threshold voltage. Thus, when the channel formation region in the oxide semiconductor includes oxygen vacancies, the transistor is likely to have normally-on characteristics (characteristics with which, even when no voltage is applied to the gate electrode, the channel exists and current flows through the transistor). Thus, impurities, oxygen vacancies, and VoH are preferably reduced as much as possible in the channel formation region in the oxide semiconductor.

The band gap of the oxide semiconductor is preferably wider than the band gap of silicon (typically 1.1 eV), further preferably greater than or equal to 2 eV, still further preferably greater than or equal to 2.5 eV, yet still further preferably greater than or equal to 3.0 eV. With use of an oxide semiconductor having a wider band gap than silicon, the off-state current of the transistor (also referred to as Ioff) can be reduced.

In a Si transistor, a short-channel effect (also referred to as SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus can suppress the short-channel effect. In other words, the short-channel effect does not appear or hardly appears in the OS transistor.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as S value), and an increase in leakage current. Here, the S value refers to the amount of change in a gate voltage which makes the drain current change by one digit in a subthreshold region at a constant drain voltage.

The characteristic length is widely used as an indicator of resistance to a short-channel effect. The characteristic length is an indicator of curving of a potential in a channel formation region. The smaller the characteristic length is, the more sharply the potential rises; thus, a smaller characteristic length indicates higher resistance to a short-channel effect.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Thus, the OS transistor has higher resistance to a short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of a short-channel effect. Thus, the OS transistor can be more suitably used as a short-channel transistor than the Si transistor. Note that the gate length refers to the length of a gate electrode in a direction in which carriers move inside a channel formation region during operation of the transistor and to the width of the bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

The configuration, structure, method, or the like described in this embodiment can be used in combination with the configuration, structure, method, or the like described in the other embodiments and the like as appropriate.

### Embodiment 3

This embodiment describes an electronic component, an electronic device, a large computer, space equipment, and a data center (also referred to as DC) that can include any of the semiconductor devices described in the above embodiments. Electronic components, electronic devices, a large computer, space equipment, and a data center in which the semiconductor device of one embodiment of the present invention is used are effective in improving performance, e.g., reducing power consumption.

### Electronic Component

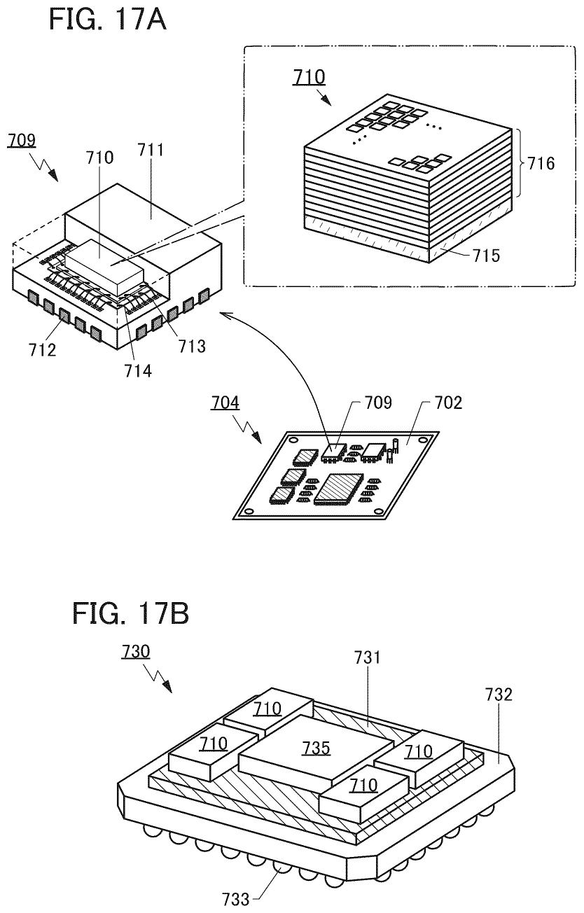

FIG. 17A is a perspective view of a substrate (a circuit board 704) provided with an electronic component 709. The electronic component 709 illustrated in FIG. 17A includes a semiconductor device 710 in a mold 711. FIG. 17A omits illustrations of some parts to show the inside of the electronic component 709. The electronic component 709 includes a land 712 outside the mold 711. The land 712 is electrically connected to an electrode pad 713, and the electrode pad 713 is electrically connected to the semiconductor device 710 via a wire 714. The electronic component 709 is mounted on a printed circuit board 702, for example. A plurality of such electronic components are combined and electrically connected to each other on the printed circuit board 702, so that the circuit board 704 is completed.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) and a bonding technique such as Cu-to-Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form as compared with the case where the memory layer 716 is formed with OS transistors. Thus, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 17B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, for example, a ceramic substrate, a plastic substrate, or a glass epoxy substrate can be used. As the interposer 731, for example, a silicon interposer or a resin interposer can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided over the interposer 731 to an electrode provided over the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

In order to achieve a wide memory bandwidth, many wirings need to be connected to an HBM. Thus, formation of minute and high-density wirings is required for an interposer on which an HBM is mounted. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, so that a poor connection between the silicon interposer and an integrated circuit provided over the silicon interposer is less likely to occur. It is particularly preferable to use a silicon interposer for a 2.5D package (2.5-dimensional mounting) in which a plurality of integrated circuits are arranged side by side over the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the monolithic stacked-layer structure using the OS transistors is suitable. A composite structure combining memory cell arrays stacked using TSV and monolithically stacked memory cell arrays may be employed.

A heat sink (radiator plate) may be provided to overlap with the electronic component 730. In the case of providing a heat sink, the heights of integrated circuits provided over the interposer 731 are preferably the same. For example, in the electronic component 730 described in this embodiment, the heights of the semiconductor devices 710 and the semiconductor device 735 are preferably equal to each other.

An electrode 733 may be provided on the bottom portion of the package substrate 732 to mount the electronic component 730 on another substrate. FIG. 17B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

### Electronic Device

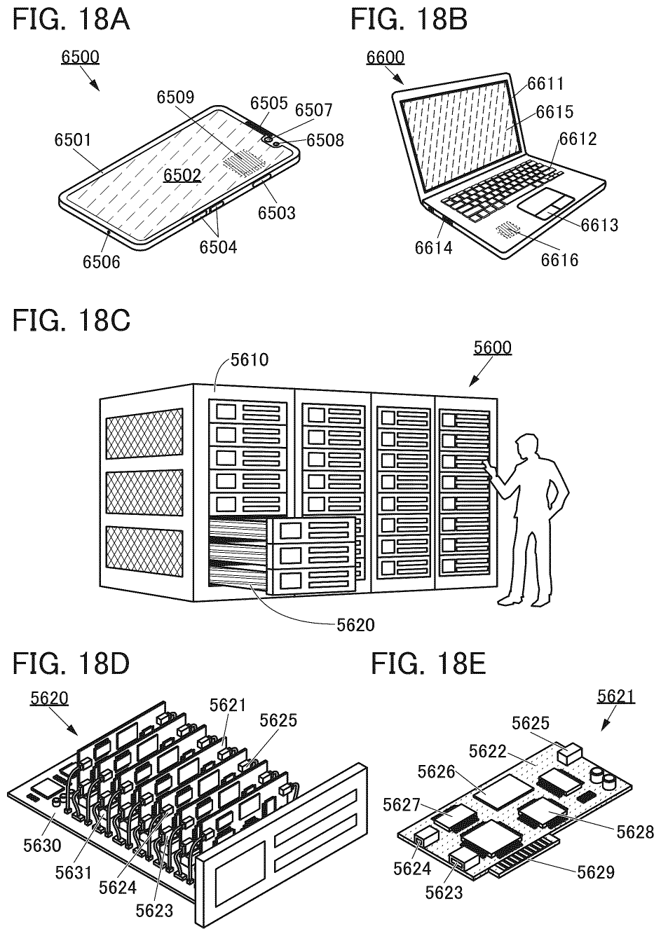

FIG. 18A is a perspective view of an electronic device 6500. The electronic device 6500 illustrated in FIG. 18A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. The control device 6509 includes one or more selected from a CPU, a GPU, and a memory device, for example. The semiconductor device of one embodiment of the present invention can be used for the display portion 6502, the control device 6509, and the like.

An electronic device 6600 illustrated in FIG. 18B is an information terminal that can be used as a laptop personal computer. The electronic device 6600 includes a housing 6611, a keyboard 6612, a pointing device 6613, an external connection port 6614, a display portion 6615, a control device 6616, and the like. The control device 6616 includes one or more selected from a CPU, a GPU, and a memory device, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### Large Computer

FIG. 18C is a perspective view of a large computer 5600. In the large computer 5600 illustrated in FIG. 18C, a plurality of rack mount computers 5620 are stored in a rack 5610. Note that the large computer 5600 may be referred to as a supercomputer.

The computer 5620 can have a structure in a perspective view illustrated in FIG. 18D, for example. In FIG. 18D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 18E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 18E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The semiconductor device 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the semiconductor device 5629 is PCIe or the like.

The connection terminal 5623, the connection terminal 5624, and the connection terminal 5625 can serve as, for example, an interface for performing power supply, signal input, or the like to the PC card 5621. As another example, they can serve as an interface for outputting a signal computed by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark) or the like.

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 709 can be used, for example.

The large computer 5600 can also function as a parallel computer. When the large computer 5600 is used as a parallel computer, large-scale computation necessary for artificial intelligence learning and inference can be performed, for example.

### Device for Space

The semiconductor device of one embodiment of the present invention can be suitably used for space equipment, such as devices processing and storing information.

The semiconductor device of one embodiment of the present invention can include an OS transistor. A change in electrical characteristics of the OS transistor due to radiation irradiation is small. That is, the OS transistor is highly resistant to radiation, and thus can be suitably used in an environment where radiation can enter. For example, the OS transistor can be suitably used in outer space.

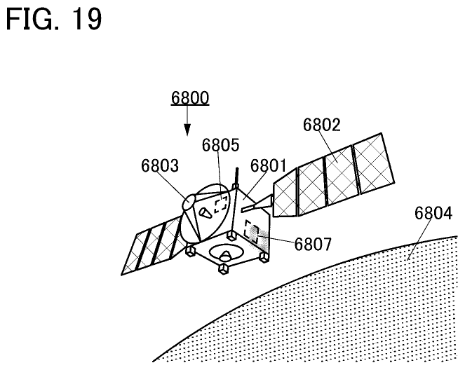

FIG. 19 illustrates an artificial satellite 6800 as an example of a device for space. The artificial satellite 6800 includes a body 6801, a solar panel 6802, an antenna 6803, a secondary battery 6805, and a control device 6807. Note that in FIG. 19, a planet 6804 in outer space is illustrated as an example. Note that outer space refers to, for example, space at an altitude greater than or equal to 100 km, and outer space described in this specification may include thermosphere, mesosphere, and stratosphere.

Although not illustrated in FIG. 19, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### Data Center

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, and the like.

With the use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved, for example. This can reduce the space of the data center.

In addition, since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve a data center that operates stably even in a high temperature environment. Thus, the reliability of the data center can be increased.

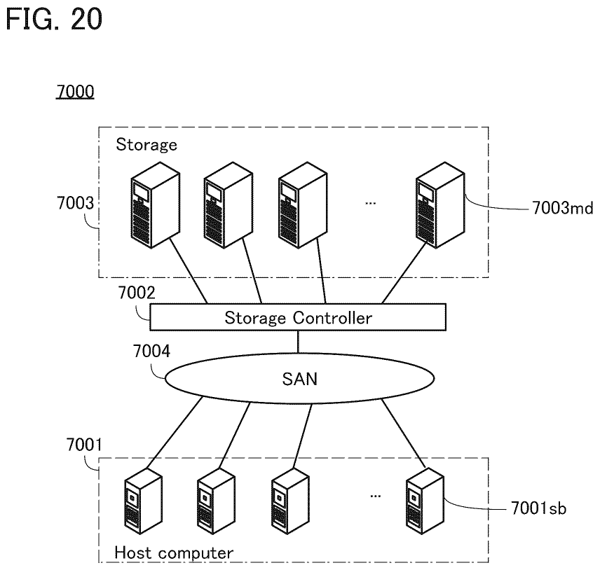

FIG. 20 illustrates a storage system that can be used in a data center. A storage system 7000 illustrated in FIG. 20 includes a plurality of servers 7001sb as a host 7001 (indicated as “Host computer” in the diagram). The storage system 7000 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer which accesses data stored in the storage 7003. The host 7001 may be connected to another host 7001 via a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in a storage to shorten data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the above-described cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

The configuration, structure, method, or the like described in this embodiment can be used in combination with the configuration, structure, method, or the like described in the other embodiments and the like as appropriate.

### Supplementary Notes on Description in this Specification and the Like

The following are notes on the description of the above embodiments and the structures in the embodiments.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, a content described in the embodiment is a content described using a variety of diagrams or a content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, even more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Thus, blocks in the block diagrams are not limited by the components described in this specification, and the description can be changed appropriately depending on the situation.

Furthermore, in the drawings, the size, the layer thickness, or the region is shown with given magnitude for description convenience. Thus, the size, the layer thickness, or the region is not limited to the illustrated scale. Note that the drawings are schematically shown for clarity, and embodiments of the present invention are not limited to shapes, values or the like shown in the drawings. For example, variations in a signal, a voltage, or a current due to noise, variations in a signal, a voltage, or a current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (or drain) terminal, a source (or drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes”or “wirings”are formed in an integrated manner, for example.

Furthermore, in this specification and the like, “voltage” and “potential” can be interchanged with each other as appropriate. The voltage refers to a potential difference from a reference potential, and when the reference potential is ground voltage, for example, the voltage can be rephrased into the potential. The ground potential does not necessarily mean 0 V. Note that potentials are relative values, and a potential applied to a wiring or the like is sometimes changed depending on the reference potential.

In this specification and the like, the terms “film” and “layer” can be interchanged with each other depending on the case or situation. For example, the term “conductive layer” can be replaced with the term “conductive film” in some cases. As another example, the term “insulating film”can be changed into the term “insulating layer”in some cases.

In this specification and the like, a switch has a function of controlling whether current flows or not by being in a conduction state (on state) or a non-conduction state (off state). Alternatively, a switch has a function of selecting and switching a current path.

In this specification and the like, channel length refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” indicates the case where A and B are electrically connected. Here, the expression “A and B are electrically connected” indicates connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” indicates connection that enables electrical signal transmission between A and B through a wiring (or an electrode) or the like, not through the above object. In other words, direct connection refers to connection that can be regarded as the same circuit diagram when represented by an equivalent circuit.

### Reference Numerals

10: semiconductor device, 20: element layer, 22: peripheral circuit, 30: element layer, 31: memory cell array, 32: memory cell, 37: transistor, 38: capacitor, 50: element layer, 51: amplifier circuit, 66A: region, 66: sense amplifier

1. A semiconductor device comprising:
a first element layer provided with a reading circuit;
a second element layer provided with an amplifier circuit; and
a third element layer provided with a memory cell,
wherein the second element layer is stacked over the first element layer,
wherein the third element layer is stacked over the second element layer,
wherein the memory cell and the amplifier circuit are electrically connected to each other through a first bit line,
wherein the amplifier circuit and the reading circuit are electrically connected to each other through a second bit line,
wherein the amplifier circuit is configured to transmit a signal corresponding to a potential of the first bit line to the second bit line,
wherein the amplifier circuit comprises a first transistor in which a first semiconductor layer comprising a channel formation region comprises an oxide semiconductor,
wherein the memory cell comprises a second transistor in which a second semiconductor layer comprising a channel formation region comprises an oxide semiconductor and a capacitor,
wherein the first semiconductor layer is provided in a direction parallel to a substrate provided with the first element layer, and
wherein the second semiconductor layer has a region provided in a direction perpendicular to the substrate provided with the first element layer.

2. The semiconductor device according to claim 1,
wherein the capacitor is provided in an opening portion provided in the third element layer, and
wherein the opening portion comprises a region overlapping with the second semiconductor layer.

3. The semiconductor device according to claim 1,
wherein the first transistor comprises a gate and a back gate, and
wherein the back gate comprises a region overlapping with the gate.

4. The semiconductor device according to claim 1,
wherein a plurality of element layers are stacked in the third element layer.

5. The semiconductor device according to claim 1,
wherein the oxide semiconductor comprises In, Ga, and Zn.

6. The semiconductor device according to claim 1,
wherein the oxide semiconductor comprises at least In.

7. A semiconductor device comprising:
a first element layer provided with a reading circuit;
a second element layer provided with an amplifier circuit; and
a third element layer provided with a memory cell,
wherein the second element layer is stacked over the first element layer,
wherein the third element layer is stacked over the second element layer,
wherein the memory cell and the amplifier circuit are electrically connected to each other through a first bit line,
wherein the amplifier circuit and the reading circuit are electrically connected to each other through a second bit line,
wherein the amplifier circuit is configured to transmit a signal corresponding to a potential of the first bit line to the second bit line,
wherein the amplifier circuit comprises a first transistor in which a first semiconductor layer comprising a channel formation region comprises an oxide semiconductor,
wherein the memory cell comprises a second transistor in which a second semiconductor layer comprising a channel formation region comprises an oxide semiconductor and a capacitor,
wherein the second transistor is stacked over the capacitor,
wherein the first semiconductor layer is provided in a direction parallel to a substrate provided with the first element layer, and
wherein the second semiconductor layer has a region provided in a direction perpendicular to the substrate provided with the first element layer.

8. The semiconductor device according to claim 7,
wherein the capacitor is provided in an opening portion provided in the third element layer, and
wherein the opening portion comprises a region overlapping with the second semiconductor layer.

9. The semiconductor device according to claim 7,
wherein the first transistor comprises a gate and a back gate, and
wherein the back gate comprises a region overlapping with the gate.

10. The semiconductor device according to claim 7,
wherein a plurality of element layers are stacked in the third element layer.

11. The semiconductor device according to claim 7,
wherein the oxide semiconductor comprises In, Ga, and Zn.

12. The semiconductor device according to claim 7,
wherein the oxide semiconductor comprises at least In.
